(19) United States
(12) Patent Application Publication
(10) Pub. No.: US 2025/0219354 A1
(43) Pub. Date: Jul. 3, 2025

(54) FMCW LIDAR BASED ON CHIP INTEGRATION

(71) Applicant: ZHUHAI YINGXUN XINGUANG TECHNOLOGY CO., LTD., Guangdong (CN)

(72) Inventor: Ruolin LI, Guangdong (CN)

(73) Assignee: ZHUHAI YINGXUN XINGUANG TECHNOLOGY CO., LTD., Guangdong (CN)

(21) Appl. No.: 18/850,567

(22) PCT Filed: Apr. 18, 2023
(86) PCT No.: PCT/CN2023/088893

§ 371 Date: Sep. 25, 2024

(30) Foreign Application Priority Data
Jun. 30, 2022 (CN) 202210755336.3
Mar. 28, 2023 (CN) 202310313406.4

(51) Int. Cl. H01S 5/14; G01S 7/481; G01S 7/4911; H01S 5/0683

(52) U.S. Cl. CPC H01S 5/141; G01S 7/4811; G01S 7/4911; H01S 5/0683

(57) ABSTRACT

A FMCW lidar based on chip integration is disclosed to comprise of an external-cavity tunable laser composed of a hybrid integration of a light-emission gain chip, a first optical waveguide, a second optical waveguide, a broadband optical feedback structure, a waveguide phase control section, a tunable waveguide filter on an integrated chip, a collimating optical lens and an optical filtering feedback device. Frequency-modulated continuous wave coherent laser ranging is achieved by the means of utilizing 1. dispersive optical element so that a solid-state angular scan of a laser beam based on its wavelength tuning can be achieved without any mechanical movement; 2. waveguide interferometer and an optical balance detector so that the linearity of wavelength tuning or chirp of the external-cavity tunable laser is monitored, calibrated and controlled. 3. a focusing optical lens, a waveguide interferometer and a balanced optoelectric detector.

### TECHNICAL FIELD

The present disclosure relates to the technical field of laser detection, and in particular to an FMCW lidar based on chip integration.

### BACKGROUND ART

More and more attention has been paid to assist driving and more advanced Autonomous Driving technology due to the convenience of work and life and huge social and economic benefits they bring about for human beings, and the application demands are developing rapidly. As the core device of sensing technology to achieve Autonomous Driving technology, lidar is one of the important guarantees for achieving safety of Autonomous Driving due to its measurement accuracy and high spatial resolution, which is an indispensable measurement means.

Faced with the requirements of performance, reliability, mass production scale and cost price for the lidars in the application scenes of Autonomous Driving, the solution based on traditional mechanical rotation-type discrete devices is facing more and more challenges. The market urgently needs a low-cost, high-reliability technical solution that can be mass-produced on a large scale. Since semiconductor chip technology has the advantages of small size, reliable performance, high repeatability, low cost and high reliability, it has become the most expected technology of Autonomous Driving lidar and the inevitable choice of product manufacturing route.

On the other hand, among the various lidar technology approaches, the frequency-modulated continuous wave or the FMCW lidar solution are based on the principle of optical coherence to achieve ranging by scanning with a laser wavelength or frequency. This has many advantages, in comparison to traditional time of flight ranging, i.e. the TOF (Time of Flight) measurement scheme, such as high measurement accuracy, strong interference and crosstalk resistance (especially against solar background light), and low laser power requirements. Especially, the FMCW lidar with a laser wavelength of 1550 nm is more friendly to human eye safety and attracts more and more attention, and it is regarded as the final choice of LiDAR for Autonomous Driving applications. The FMCW lidar can measure simultaneously the velocity of an object or a fast moving vehicle as well as the three-dimensional position of the object, so it is also called a four-dimensional (4D) lidar.

The development of photonic integrated chips is converging towards CMOS-based silicon semiconductor IC platforms, specifically represented by silicon photonic technology, i.e. large-scale integration and fabrication of high-performance, low-cost optical devices using CMOS semiconductor technology on silicon wafers. In the development and application of silicon optical technology, since silicon is an indirect bandgap semiconductor and cannot directly emit light, the light-emission function is achieved by integrating a compound semiconductor light-emission chip. There are two common approaches for this, wherein one is butt-coupling, i.e. coupling a compound semiconductor light-emission gain chip or an active chip with a silicon optical or a passive photonic integrated chip via an end-face waveguide, so that light emitted from an active chip optical waveguide is coupled into a corresponding optical waveguide of the passive chip by means of optical mode overlap. The other is optical evanescent wave coupling, i.e. flip-chip mounting a compound semiconductor light-emission gain chip or an active chip on the surface of the silicon optical chip, and light transmitted in the active chip optical waveguide is coupled into a corresponding optical waveguide of the silicon optical or passive photonic integrated chip through an optical evanescent wave.

In view of the foregoing, there is a need for a cost-effective semiconductor-chip lidar solution to meet the demand for high-end ranging and 3D sensing application, for example, in Autonomous Driving applications.

### SUMMARY OF INVENTION

The technical problem to be solved by the present disclosure is to provide an FMCW lidar based on chip integration.

The technical solution adopted by the present disclosure to solve the technical problem thereof is described in the following content:

An FMCW lidar based on chip integration, characterized by including: a light-emission gain chip, an integrated chip, a collimating optical lens and an optical filtering feedback device;
the FMCW lidar constitutes an external-cavity tunable laser as laser source with the following structure that:
the integrated chip is provided with an optical waveguide loop containing a first optical waveguide and a second optical waveguide; two ports of the first optical waveguide are respectively connected to a broadband optical feedback structure and a tunable waveguide filter; a first port of the second optical waveguide is connected to the tunable waveguide filter, and a second port of the second optical waveguide is configured for emitting light out of the integrated chip; and the first optical waveguide or the second optical waveguide passes through a waveguide phase control section (phase control or PC); and
the light-emission gain chip is capable of generating broadband spontaneous emission photons based on electro-optic conversion during current injection and emit them through its optical waveguide, and light emitted therefrom is coupled to the first optical waveguide or the second optical waveguide; and the collimating optical lens and the optical filtering feedback device are sequentially placed on an exit optical path of the second optical waveguide.

The present disclosure involves four cases regarding the placements and positions of the waveguide phase control section and the light-emission gain chip: the case where the first optical waveguide passes through the waveguide phase control section and the light emitted from the light-emission gain chip is coupled to the first optical waveguide as shown in FIG. 1a, and three cases of “the second optical waveguide passing through the waveguide phase control section” and/or “the light emitted from the light-emission gain chip being coupled to the second optical waveguide” not shown in the drawings.

In the technical solution:

The broadband optical feedback structure is capable of reflecting light along an original path of an incident direction;
the waveguide phase control section is capable of controlling a round trip optical path of a photon in the external-cavity tunable laser to be an integer multiple of a wavelength of a laser beam emitted by the external-cavity tunable laser, and the round trip optical path is along a path of the broadband optical feedback structure, the optical waveguide of the light-emission gain chip, the first optical waveguide and the waveguide phase control section, the tunable waveguide filter, the second optical waveguide, the collimating optical lens and the optical filtering feedback device, after reaching the optical filtering feedback device in a forward direction from the broadband optical feedback structure, returning back to the optical path of the broadband optical feedback structure in a reverse direction from the optical filtering feedback device;
the tunable waveguide filter has the following characteristics that: light coupled to the second optical waveguide by the first optical waveguide being filtered by the tunable waveguide filter and light coupled to the first optical waveguide by the second optical waveguide being filtered by the tunable waveguide filter are both denoted as transmission light; a light intensity of the transmission light has a transmission spectrum composed of several transmission peaks in a connection manner and distributed in a comb shape as shown in FIG. 1c, and an interval between peak wavelengths of any two adjacent transmission peaks is a fixed Free Spectral Range; and the tunable waveguide filter is capable of synchronously tuning the peak wavelengths of all the transmission peaks together, i.e., translating the transmission spectrum shown in FIG. 1c along the wavelength; and
the optical filtering feedback device is capable of reflecting light of wavelength in a reflection band along the original path of the incident direction, with reference to FIG. 1d, the reflection band having a fixed central wavelength and a reflection wavelength bandwidth smaller than, preferably close to, the Free Spectral Range. In this way, the peak wavelength of the transmission peak of which the peak falls within the reflection band is the wavelength of the laser beam.

Thus, taking the case of the first optical waveguide passing through the waveguide phase control section and the light emitted by the light-emission gain chip being coupled into the first optical waveguide as an example, the operation principle of the external-cavity tunable laser of the present disclosure is described as follows.

Firstly, the light-emission gain chip serves as a photon source and a laser amplification source for the external-cavity tunable laser, and the light emitted by the light-emission gain chip is coupled into the first optical waveguide of the integrated chip, and is split into left-propagating light and right-propagating light according to the propagation direction, and the left-propagating light in the first optical waveguide reaches the broadband optical feedback structure, it is reflected in the original path and is coupled back to the optical waveguide of the light-emission gain chip, and then propagates in the right direction to be coupled into the first optical waveguide to become right-propagating light; after passing through the waveguide phase control section, the right-propagating light in the first optical waveguide is filtered by the tunable waveguide filter to become a transmission light having a transmission spectrum as shown in FIG. 1c and coupled to the second optical waveguide; and transmission light in the second optical waveguide emerges from the second port of the second optical waveguide out of the integrated chip, and is incident on the optical filtering feedback device after being collimated by the collimating optical lens.

Then, with reference to FIG. 1e, the transmission light incident on the optical filtering feedback device has transmission peaks located within the reflection band of the optical filtering feedback device in the transmission spectrum shown in FIG. 1c, namely, the reflected transmission peak would be reflected by the optical filtering feedback device according to the reflectivity thereof in the original path, so as to be coupled back to the optical waveguide of the light-emission gain chip along the path of the optical filtering feedback device, the collimating optical lens, the second optical waveguide, the tunable waveguide filter, the first optical waveguide and the waveguide phase control section, and then propagates in the left direction to be coupled to and incident on the broadband optical feedback structure, and then reflected back to the first optical waveguide from the broadband optical feedback structure to propagate to the right direction so as to continuously repeat the above-mentioned process together with the light coupled into the first optical waveguide from the optical waveguide of the light-emission gain chip, so that photons are resonantly amplified between the broadband optical feedback structure of the external-cavity tunable laser and the optical filtering feedback device, thereby achieving amplification of a reflected transmission peak in the external-cavity tunable laser, and forming a laser beam emitted by the external-cavity tunable laser.

In above process, the peak wavelength of the transmission peak being reflected is the wavelength of the laser beam, and the wavelength tuning is performed by controlling the tunable waveguide filter, i.e. simultaneously tuning the peak wavelengths of all the transmission peaks of the transmission spectrum shown in FIG. 1c, so that the peak wavelength of the transmission peak being reflected changes within the reflection band, i.e. the wavelength of the laser beam can be tuned accordingly, thereby achieving the rapid wavelength tuning of the laser beam output by the external-cavity tunable laser within the reflection band range of the optical filtering feedback device, and the external-cavity tunable laser has a simple, reliable and rapid laser wavelength tuning mechanism.

Furthermore, since the reflection wavelength bandwidth of the reflection band is less than the Free Spectral Range, single-mode tuning frequency operation of the laser beam output by the external-cavity tunable laser is achieved. Besides, since the Free Spectral Range of the tunable waveguide filter can reach 10+ nanometers or even tens of nanometers, in the optical communication band of 1550 nm, the external-cavity tunable laser can achieve continuous wavelength tuning of the of 10+ nanometers or even tens of nanometers and can cover a tuning range of hundreds of nanometers.

In addition, for the three cases of alternatively “the second optical waveguide passing through the waveguide phase control section” and/or “the light emitted from the light-emission gain chip being coupled to the second optical waveguide”, the operation principle is the same as that described above, and the description thereof will not be repeated.

As one of preferred exit scheme of the laser beam in the present disclosure: as shown in FIGS. 1a to 5, the external-cavity tunable laser emits the laser beam through the optical filtering feedback device in the manner that the broadband optical feedback structure is a high-reflectivity broadband optical feedback structure with a reflectivity higher than a preset value, so that most light incident on the broadband optical feedback structure is reflected along the original path of the incident direction as possible; and the reflectivity of the optical filtering feedback device is lower than the preset value, so that the light incident on the optical filtering feedback device with wavelength within the reflection band is divided into two parts, one part is reflected along the original path of the incident direction and participates in the amplification of the reflected transmission peak in the external-cavity tunable laser, and the other part is transmitted through the optical filtering feedback device and exits as a laser beam.

For example, the reflectivity of the broadband optical feedback structure may be no less than 99% and the reflectivity of the optical filtering feedback device may be 50%, whereby photons in the external-cavity tunable laser are resonantly amplified by reflection between the optical filtering feedback device and the broadband optical feedback structure, and 50% of the photons may pass through the optical filtering feedback device and exit as a laser beam.

As a preferred implementation of the present disclosure, as shown in FIGS. 2a-4b, the FMCW lidar is provided with an optical switch and n free-space optical feedback channels, n≥2; In the figures, the first free-space optical feedback channel to the nth free-space optical feedback channel are sequentially denoted as 401, . . . , 40n; and the optical switch should have a large operation wavelength bandwidth.

Each of the free-space optical feedback channels is provided with one optical filtering feedback device, and so that there are n optical filtering feedback devices corresponding to n free-space optical feedback channels, exit directions of each optical paths of the n optical filtering feedback devices are different, the central wavelengths of the reflection bands of the n optical filtering feedback devices are different from each other and intervals therebetween are integer multiples of the Free Spectral Range, while the reflection bands of the n optical filtering feedback devices do not overlap each other, and the reflection wavelength bandwidths of the n optical filtering feedback devices can be the same or different; for example, with reference to FIG. 2c, n optical filtering feedback devices corresponding to n free-space optical feedback channels have their reflection bands 400a1, . . . , 400an in sequence, their central wavelengths of reflection bands are λ₁, . . . , λₙ in sequence, and their reflection wavelength bandwidths are FB1, . . . , FBn in sequence.

The optical switch is capable of selecting any one of the n free-space optical feedback channels for optical coupling with the second optical waveguide such that each free-space optical feedback channel can construct an exit optical path for the second optical waveguide.

Thus, the present disclosure provides an optical switch and n free-space optical feedback channels that operate in a principle as to be described below.

With reference to FIGS. 1c and 2c, as previously stated, the light is filtered by the tunable waveguide filter into a transmitted light with a transmission spectrum as shown in FIG. 1c and coupled to the second optical waveguide, and transmits out of the integrated chip via the second port of the second optical waveguide; by means of the optical switch, a free-space optical feedback channel is chosen for optical coupling to the second optical waveguide, enabling the above-mentioned transmitted light to be incident on the optical filtering feedback device corresponding to the chosen one of the n free-space optical feedback channels, whereby, with the help of the optical switch, a part of the light having a transmission light wavelength within the reflection band of the optical filtering feedback device in the selected channel is reflected in the original path, and the other part transmits through the selected optical filtering feedback device to be output as the laser beam; for example, the optical switch can select the optical filtering feedback device corresponding to the reflection band 400a1 (or the reflection band 400an) to reflect and exit the wavelength of peak of the transmission light within the reflection band 400a1 (or the reflection band 400an) in the original path; and, therefore, the optical filtering feedback devices of n different free-space optical feedback channels can be selected by the optical switch, so that the laser beam output by the external-cavity tunable laser can be emitted from the corresponding n different directions, and the wavelength tuning of the laser beam output by the external-cavity tunable laser in the corresponding n different reflection band wavelength ranges can be achieved, so as to achieve the wavelength tuning of the laser beam output by the external-cavity tunable laser within more wavelength regions and a wider wavelength range and more choices of the exit directions.

Preferably, as shown in FIGS. 1c to 1e and FIG. 2c, the interval between any two adjacent central wavelengths of the reflection band of the n optical filtering feedback devices is the Free Spectral Range; and the reflection bands of all the n optical filtering feedbacks have a reflection wavelength bandwidth smaller than and close to the Free Spectral Range, and the interval between any two adjacent reflection bands is smaller than a preset value, so that the reflection bands of the n optical filtering feedback devices are close to the approximately continuous spectrum shown in FIG. 2c. Thus, since the Free Spectral Range of the tunable waveguide filter can be 10+ or even few tens of nanometers, it is achievable to tune the wavelength the external-cavity tunable laser over a hundred nanometers or even wider wavelength range by switching between the n optical filtering feedback devices to add up more reflection wavelength bands.

As one of the preferred implementations to realize the selection of n free-space optical feedback channels, as shown in FIGS. 2a and 2b, the optical switch is a planar waveguide optical switch disposed on the integrated chip; n branch optical waveguides on the integrated chip are provided corresponding to the n free-space optical feedback channels; and the second port of the second optical waveguide is connected to a main port of the planar waveguide optical switch, one ends of the n branch optical waveguides are connected to the planar waveguide optical switch and the other ends of the n branch optical waveguides are connected to a second facet of the integrated chip;
and each of the free-space optical feedback channels is provided with one collimating optical lens and one optical filtering feedback device; and the collimating optical lens and the optical filtering feedback device of each of the free-space optical feedback channels are successively disposed on an exit optical path of the corresponding branch optical waveguides.

Thus, different external-cavity tunable lasers can be constructed by selecting different branch optical waveguides for optical coupling with the second optical waveguide through the planar waveguide optical switch; for example, when the branch optical waveguide corresponding to the free-space optical feedback channel 401 is selected, the external-cavity tunable laser is composed of a hybrid integration of the broadband optical feedback structure, the light-emission gain chip, the first optical waveguide, the waveguide phase control section, the tunable waveguide filter, the second optical waveguide, the planar waveguide optical switch, the branch optical waveguide corresponding to the free-space optical feedback channel 401, the collimating optical lens corresponding to the free-space optical feedback channel 401 and the optical filtering feedback device; when the branch optical waveguide corresponding to the free-space optical feedback channel 40n is selected, the external-cavity tunable laser is composed of a hybrid integration of the broadband optical feedback structure, the light-emission gain chip, the first optical waveguide, the waveguide phase control section, the tunable waveguide filter, the second optical waveguide, the planar waveguide optical switch, the branch optical waveguide corresponding to the free-space optical feedback channel 40n, the collimating optical lens corresponding to the free-space optical feedback channel 40n and the optical filtering feedback device.

As a second preferred implementation of implementing n free-space optical feedback channels, as shown in FIGS. 3a and 3b, the optical switch is a free-space optical switch, and the free-space optical switch has one main optical port and n branch optical ports respectively corresponding to the n free-space optical feedback channels; and the n free-space optical feedback channels share one collimating optical lens, and each of the free-space optical feedback channels is provided with one optical filtering feedback device; and
the second port of the second optical waveguide is connected to a second facet of the integrated chip, the collimating optical lens and the main optical port of the free-space optical switch are successively disposed on the exit optical path of the second optical waveguide, and the n branch optical ports of the free-space optical switch are respectively located on incident optical paths of the optical filtering feedback devices of the n free-space optical feedback channels.

Thus, different external-cavity tunable lasers can be constructed by selecting different branch optical ports for optical transmission with the main optical port by the free-space optical switch.

Preferably, as shown in FIGS. 4a and 4b, the free-space optical switch is a micro-electromechanical mirror (MEMs mirror).

The free-space optical switch may not be limited to a micro-electromechanical system (MEMs), a liquid crystal optical device, an optical meta-surface device, or a combination of any plurality thereof.

As another preferred implementation of the present disclosure, as shown in FIGS. 2a and 4b, exit directions of optical paths of the optical filtering feedback devices of the n free-space optical feedback channels have a fan-out distribution at evenly spaced angles; and
a dispersive optical element is disposed on the exit optical path of the optical filtering feedback device corresponding to the free-space optical feedback channel.

The dispersive optical element can be, but is not limited to any one of, or any combination of multiple of, a diffraction grating, a diffractive optical element (DOE), a holographic optical element (HOW), and an optical meta-surface device.

Thus, the present disclosure provides n free-space optical feedback channels in combination with the dispersive optical element, the operating principle of which is described as follows.

When the laser beam of the external-cavity tunable laser exits through any one of the free-space optical feedback channels, the laser beam output by the external-cavity tunable laser exits through the dispersive optical element along the free-space optical feedback channel, and since the exit angle of the dispersive optical element will change correspondingly with the wavelength tuning of the incident laser light, when the wavelength of the laser is tuned within the reflection band of the optical filtering feedback device by the tunable waveguide filter, the exit angle of the laser beam through the dispersive optical element will change in accordance with the wavelength tuning, so that a solid angular scanning of a laser beam driven by wavelength tuning is achieved with no mechanical movement of any kind;

Furthermore, in cooperation of evenly angle-spaced fan-out distribution of the exit beam direction of the n free-space optical feedback paths, a solid-state laser beam angle scanning can be performed via the dispersive optical element on each free-space optical feedback channel along the exit direction of the laser light corresponding to the free-space optical feedback channel; and
thus, the present disclosure enables a wide angular range scan of laser detection.

Preferably, as one preferred high-reflectivity broadband optical feedback structure, as shown in FIG. 1a, the high-reflectivity broadband optical feedback structure as the broadband optical feedback structure includes that one end of the first optical waveguide extends to a first facet of the integrated chip, and the first facet of the integrated chip is coated with a broadband high-reflection film with a reflectivity higher than the preset value, such that light incident on the broadband optical feedback structure is reflected along the original path at the broadband high-reflection film.

Preferably, as a second preferred high-reflectivity broadband optical feedback structure, as shown in FIG. 7a, the high-reflectivity broadband optical feedback structure as the broadband optical feedback structure includes that the optical waveguide emitting light from the light-emission gain chip is butt-coupled to an facet of the first optical waveguide or the second optical waveguide through the right facet of the light-emission gain chip, such that the light emit by the light-emission gain chip is coupled to the first optical waveguide or the second optical waveguide; and the left facet of the light-emission gain chip is coated with a broadband high-reflection film having a reflectivity higher than the preset value, such that light incident on the broadband optical feedback structure is reflected along the original path at the broadband high-reflection film.

Preferably, as a third preferred high-reflectivity broadband optical feedback structure, as shown in FIG. 5, a high-reflectivity broadband optical feedback structure as the broadband optical feedback structure includes: a circled broadband waveguide loop mirror disposed on the integrated chip; and the optical waveguide of the light-emission gain chip and the first optical waveguide are coupled and they are inbetween the broadband waveguide loop mirror and the tunable waveguide filter.

As the second preferred way of exiting the laser beam in the present disclosure, as shown in FIG. 6, the external-cavity tunable laser emits the laser beam through the broadband optical feedback structure in such manner that a reflectivity of the optical filtering feedback device is higher than the preset value, such that as much light incident on the optical filtering feedback device is reflected along the original path of the incident direction as possible; an end of the first optical waveguide is connected to a first facet of the integrated chip, and the broadband optical feedback structure is a broadband reflection film coated on the first facet of the integrated chip with a reflectivity lower than the preset value; and a second collimating optical lens is placed accordingly on the exit optical path of the first optical waveguide in order to achieve collimation for exit laser beam.

For example, the reflectivity of the above-mentioned optical filtering feedback device may be 99% or higher, and the reflectivity of the broadband reflection film as the broadband optical feedback structure may be 50%, whereby photons in the external-cavity tunable laser are reflected and resonantly amplified between the optical filtering feedback device and the broadband reflection film as the broadband optical feedback structure, and 50% of the photons may pass through the broadband reflection coating of the broadband optical feedback structure to be emitted as the laser beam.

As another preferred implementation of the present disclosure, as shown in FIG. 1a, the FMCW lidar further includes a dispersive optical element; and the dispersive optical element is placed on an exit optical path of the output beam of the external-cavity tunable laser.

For example, for the FMCW lidar shown in FIG. 1a, the laser beam of the external-cavity tunable laser exits through the optical filtering feedback device, and the dispersive optical element is placed in the exit beam path of the optical filtering feedback device.

As another example, for the FMCW lidar shown in FIG. 6, the laser beam of the external-cavity tunable laser exits through the broadband optical feedback structure and the second collimating optical lens, and then the dispersive optical element is placed on the exit optical path of the broadband optical feedback structure and the second collimating optical lens.

Consequently, the present disclosure provides the dispersive optical element, the operating principle of which is as follows.

The laser beam output by the external-cavity tunable laser exits through the dispersive optical element, and since the exit angle of the dispersive optical element changes correspondingly with the wavelength tuning of the incident laser light, when the laser beam is wavelength tuned within the reflection band range of the optical filtering feedback device through the tunable waveguide filter, the exit angle of the laser beam exiting through the dispersive optical element changes in accordance with the wavelength tuning, so that a solid angular scanning of a laser beam driven by wavelength tuning is achieved in the present disclosure without mechanical movement of any kind.

The dispersive optical element can be, but is not limited to any one of, or any combination of multiple of, a diffraction grating, a diffractive optical element (DOE), a holographic optical element (HOE), and an optical meta-surface device.

As another preferred implementation of the present disclosure, as shown in FIGS. 1a-6, the integrated chip is further provided with a third optical waveguide, a fourth optical waveguide, an on-chip monitoring delay-line waveguide Mach-Zehnder Interferometer and a first balanced optoelectric detector;
a first port of the third optical waveguide and a first port of the fourth optical waveguide are respectively connected to the tunable waveguide filter, and the tunable waveguide filter also has the following characteristics that: light coupled to the third optical waveguide by the first optical waveguide via the tunable waveguide filter and light coupled to the fourth optical waveguide by the second optical waveguide via the tunable waveguide filter are both denoted as filtered light; and a light intensity of the filtered light has a spectrum complementary to the transmission spectrum, as shown in FIG. 1b; and
as a coupling port of the external-cavity tunable laser, laser light exiting any one of a second port of the third optical waveguide and a second port of the fourth optical waveguide is transmitted to the first balanced optoelectric detector through the on-chip monitoring delay-line Waveguide Mach-Zehnder Interferometer (MZI); among them, FIG. 1a, FIG. 2a to FIG. 4b show a case where light emitted from the second port of the third optical waveguide enters the on-chip monitoring delay-line Waveguide MZI, and FIG. 6 shows a case where light emitted from the second port of the fourth optical waveguide enters the on-chip monitoring delay-line Waveguide MZI.
a structure of the on-chip monitoring delay-line Waveguide MZI includes that: light input from an input port of the on-chip monitoring delay-line Waveguide MZI is split by an 1×2 waveguide coupler and then respectively coupled into a first waveguide arm and a second waveguide arm, the second waveguide arm is provided with a waveguide optical delay-line loop, and light transmitted in the first waveguide arm and the second waveguide arm converges and is mixed in a first 2×2 waveguide coupler and then split into two paths to output; and
the two paths of light output by the first 2×2 waveguide coupler are respectively coupled into two optical detectors of the first balanced optoelectric detector.

Thus, since the length of the waveguide optical delay-line loop (i.e. time delay) on the second waveguide arm is fixed, so the change of differential light frequency from two arms of the on-chip monitoring delay Waveguide MZI with time is obtained through the demodulation of signals from the first balanced optoelectric detector, thus the output of the balanced optoelectric detector can be used as feedback to monitor, calibrate and control the wavelength tuning linearity or chirp of the external-cavity tunable laser.

As another preferred implementation of the present disclosure, as shown in FIGS. 1a-6, the FMCW lidar further includes a focusing optical lens, and the integrated chip is further provided with a third optical waveguide, a fourth optical waveguide, a fifth optical waveguide, a signal demodulation Waveguide MZI and a second balanced optoelectric detector;
a first port of the fifth optical waveguide is connected to a facet of the integrated chip, and light emitted by a second port of the fifth optical waveguide is input into a second input port of the signal demodulation Waveguide MZI; and the focusing optical lens is placed on an incident optical path of the first port of the fifth optical waveguide, and the focusing optical lens and the laser beam emitted by the external-cavity tunable laser are located on a same side of the integrated chip;
a first port of the third optical waveguide and a first port of the fourth optical waveguide are respectively connected to the tunable waveguide filter, and the tunable waveguide filter also has the following characteristics that: light coupled to the third optical waveguide by the first optical waveguide via the tunable waveguide filter and light coupled to the fourth optical waveguide by the second optical waveguide via the tunable waveguide filter are both denoted as filtered light; and a light intensity of the filtered light has a spectrum complementary to the transmission spectrum, as shown in FIG. 1b; and
as an out-coupling port of the external-cavity tunable laser, laser light exiting any one of a second port of the third optical waveguide and a second port of the fourth optical waveguide is input into a first input port of the signal demodulation Waveguide MZI; among them, FIG. 1a, FIG. 2a to FIG. 4b show a case where light emitted from the second port of the fourth optical waveguide enters the signal demodulation Waveguide MZI, and FIG. 6 shows a case where light emitted from the second port of the third optical waveguide enters the signal demodulation Waveguide MZI.
the signal demodulation of Waveguide MZI constitutes that light input from the first input port and the second input port of the signal demodulation Waveguide MZI converges and is mixed in a second 2×2 waveguide coupler, and then is split into two paths and coupled into a third waveguide arm and a fourth waveguide arm, and then converges and is mixed in a third 2×2 waveguide coupler, and then split into two paths to output; and
the two paths of light output by the third 2×2 waveguide coupler are coupled into two optical detectors of the second balanced optoelectric detector respectively.

Consequently, when the laser beam emitted from the external-cavity tunable laser is steered to irradiate the detection target, a signal light reflected or scattered by the detection target is coupled into the fifth optical waveguide via the focusing optical lens and transmitted into the second input port of the signal demodulation Waveguide MZI to participate in coherent demodulation. The focusing optics can be optical devices such as a high numerical aperture (NA) lens front-end optics, optical polarization splitting element, optical switching element, beam combination element, etc., so as to have the signal light to be coupled into the fifth optical waveguide in a TE polarization only.

The light from the second input port of the signal demodulation Waveguide MZI, as a reference light or a local oscillator, together with the signal light from the first input port of the signal demodulation Waveguide MZI, is coherently demodulated through the signal demodulation Waveguide MZI and the second balanced optoelectric detector. Since a tuning rate of the wavelength or frequency of the external-cavity tunable laser is pre-determined and known, and the round-trip time of the laser light from the external-cavity tunable laser to the detection target can be obtained from the frequency difference generated through the coherent demodulation with the Waveguide MZI and the second balanced optoelectric detector, and next the distance from the FMCW lidar to the detection target can be obtained, thus achieving frequency-modulated continuous wave (FMCW) coherent laser ranging.

Furthermore, with a large-angle laser beam scanning achieved by the n free-space optical feedback channels and the dispersive optical element, the present disclosure achieves frequency-modulated continuous-wave (FMCW) ranging with high-resolution, large-angle range solid beam scan.

As one preferable way of coupling the light emitted from the light-emission gain chip into the optical waveguide of the integrated chip: as shown in FIG. 7a, light emitted by the light-emission gain chip is coupled into the optical waveguide of the integrated chip via butt-coupling, i.e., the integrated chip is provided with a etched trench, the light-emission gain chip is flip-chip mounted in the trench, and a right facet of the light-emission gain chip is coated with an optical anti-reflection film; and a facet of the first optical waveguide or the second optical waveguide is coated with an optical anti-reflection film and extends to the etched trench so as to be butt-coupled with the light emitting optical waveguide of the light-emission gain chip at the right facet of the Gain chip, and a left facet of the light-emission gain chip is coated with a reflection film having a reflectivity higher than a predetermined value as another feedback mirror of the external-cavity tunable laser, so that light emitted from the light-emission gain chip is coupled into the first optical waveguide or the second optical waveguide by means of optical mode overlap.

As a second preferable way of coupling the light emitted from the light-emission gain chip into the optical waveguide of the integrated chip: as shown in FIG. 7b, light emitted by the light-emission gain chip is coupled into the optical waveguide of the integrated chip by means of evanescent wave coupling, i.e., the light-emission gain chip is flip-chip mounted on a surface of the integrated chip, and the optical waveguide of the light-emission gain chip is coupled to the first optical waveguide or the second optical waveguide, so that light emitted by the light-emission gain chip is coupled into the first optical waveguide or the second optical waveguide through an optical evanescent wave via the optical waveguide thereof.

The light-emission gain chip can be a III-V compound semiconductor active gain chip or a light source chip, and the III-V compound semiconductor active gain chip is composed of common compound semiconductor materials, such as InP series in III-V group.

The integrated chip can be a silicon optical integrated chip or a passive photonic integrated chip.

Preferably, the second facet of the integrated chip is coated with a broadband optical anti-reflection film.

The waveguide phase control section manages the round trip optical path of the photon within the cavity of the external-cavity tunable laser to be an integral multiple of a wavelength of the laser light emitted by the external-cavity tunable laser, it is implemented (but not limited to) in such a manner that the integrated chip is formed with a first metal electrode near the waveguide phase control section, and the first metal electrode changes an optical refractive index of a corresponding optical waveguide constituting the waveguide phase control section through a thermo-optic effect or an electro-optic effect so as to change a phase of light transmitting through the waveguide phase control section, ensuring that the round trip optical path is an integral multiple of the wavelength of the laser beam. The thermo-optic effect is that heating by the first metal electrode changes the temperature of the corresponding waveguide, which changes the refractive index of the waveguide through thermo-optic coefficient of refractive index. The electro-optic effect is that changing of the current on the first metal electrode changes the refractive index of the waveguide through the electro-optical coefficient of refractive index.

The tunable waveguide filter tunes simultaneously the peak wavelengths of all transmission peaks together, i.e., the way of shifting the transmission spectrum along the wavelength as shown in FIG. 1c can be (but is not limited to) that the integrated chip is formed with a second metal electrode near the tunable waveguide filter, and the second metal electrode changes an optical refractive index of a corresponding optical waveguide constituting the tunable waveguide filter through a thermo-optic effect or an electro-optic effect so as to change a resonance frequency of the tunable waveguide filter to achieve wavelength tuning of the laser beam. The thermo-optic effect is that heating by the second metal electrode changes the temperature of the corresponding waveguide, which changes the refractive index of the waveguide. The electro-optic effect is that changing of the current on the second metal electrode changes the refractive index of the waveguide through the electro-optical effect.

The tunable waveguide filter can be, but is not limited to, integrated photonic component such as a tunable waveguide ring resonator, a sampled grating, a waveguide Bragg grating, a waveguide transmission grating with periodic transmission peaks, a super-structure grating, and a series of waveguide MZI interferometers; a tunable waveguide ring resonator is preferably used in the embodiment of the present disclosure as shown in the drawings.

The optical filtering feedback device can be, but is not limited to, any of, or any combination of multiple of, a thin-film optical reflection filter, a broadband diffraction grating, and an optical meta-surface device.

With reference to FIG. 8a and FIG. 8b, the optical filtering feedback device is composed of a thin-film optical channel transmission filter and a thin-film optical broadband reflection filter, and the thin-film optical channel transmission filter and the thin-film optical broadband reflection filter are successively placed on an exit optical path of the collimating optical lens, the optical axis of the thin-film optical channel transmission filter has an inclined angle with respect to an optical axis of the collimating optical lens, and the optical axis of the thin-film optical broadband reflection filter is coaxial with the optical axis of the collimating optical lens;

With reference to FIG. 8b, the thin-film optical channel transmission filter has the spectrum characteristic 410A shown in the figure, namely, it only transmits light within a transmission band, the transmission band has a fixed central wavelength, and the wavelength bandwidth of the transmission band is less than and preferably close to the Free Spectral Range, so as to ensure the single-mode frequency selection of the external-cavity tunable laser; and
with reference to FIG. 8b, the thin-film optical broadband reflection filter has the spectral characteristics 420A shown in the figure, i.e. it is capable of reflecting light along an original path of an incident direction at certain reflectivity.

Thus, the light incident on the optical filtering feedback device via the collimating optical lens is divided into reflection light reflected by the thin-film optical channel transmission filter and transmission light transmitted through the thin-film optical channel transmission filter; due to the inclined arrangement of the thin-film optical channel transmission filter, the reflected light cannot be coupled back to the second optical waveguide through the collimating lens, while the transmission light can be coupled back to the second optical waveguide through the thin-film optical channel transmission filter and the collimating lens after being reflected at the thin-film optical broadband reflection filter, and it is achieved that the optical filtering feedback device reflects the light of wavelength within the reflection band shown in FIG. 1d along the original path of the incident direction.

In addition, in the present disclosure, all the optical parts or functions not in free-space are implemented on the integrated chip, such as light-transport optical waveguide, the waveguide phase control section, the tunable waveguide filter, the MZI waveguide interferometer, the metal electrode, the waveguide optical delay loop, the balanced optoelectric detector, etc. can be monolithically integrated on the integrated chip.

Advantages of the present disclosure compared with prior art are described as follows.

Firstly, with reference to FIGS. 1a to 8b, in the present disclosure the external-cavity tunable laser A composed of a hybrid integration of the light-emission gain chip 100, the first optical waveguide 201 of the integrated chip 200, the second optical waveguide 202, the broadband optical feedback structure 210, the waveguide phase control section 220, the tunable waveguide filter 230, the collimating lens 300 and the optical filtering feedback device 400, and the tunable waveguide filter 230 and the optical filtering feedback device 400 together form a composite filtering feedback of the external-cavity tunable laser A, and thus fast wavelength tuning of the laser beam L output by the external-cavity tunable laser A within the range of the reflection band 400a of the optical filtering feedback device 400 is achieved; furthermore, since the reflection wavelength bandwidth FB of the reflection band 400a is less than the Free Spectral Range (FSR), the single-mode operation and wavelength tuning of the laser beam L output by the external-cavity tunable laser A is achieved; therefore, the external-cavity tunable laser A in the present disclosure offers a simple, reliable and fast wavelength tuning mechanism for the laser beam L, and can achieve continuous wavelength tuning of 10+ nanometers or even tens of nanometers, and can cover a tuning range of hundreds of nanometers at the optical communication band of 1550 nanometers.

Secondly, with reference to FIGS. 2a and 4b, by providing an optical switch and n free-space optical feedback channels, the present disclosure enables selection of the optical filtering feedback devices 400 from n different free-space optical feedback channels via the optical switch so as to enable the laser beam L of the external-cavity tunable laser A to exit in n different directions, and enable the wavelength tuning of the external-cavity tunable laser A covering the wavelength range of the n different reflection bands 400a, so as to have the laser to tune in more wavelength regions and a wider wavelength range and to exit in more direction of choice.

Thirdly, with reference to FIG. 1a, the present disclosure enables the solid-state angular scanning of beam driven by wavelength tuning without mechanical movement of any kind through providing a dispersive optical element 600.

Fourthly, with reference to FIGS. 2a to 4b, the present disclosure enables a wide angular range of laser beam scan by providing n free-space optical feedback channels in cooperation with the dispersive optical element 600 placed on each free-space optical feedback channel.

Fifthly, with reference to FIGS. 1a-6, the present disclosure can monitor, calibrate and control the wavelength tuning linearity or chirp of the external-cavity tunable laser A by providing the on-chip monitoring delay-line Waveguide MZI 250 and the first balanced optoelectric detector 260 on the integrated chip 200, using the output of the first balanced optoelectric detector 260 as the feedback.

Sixthly, with reference to FIGS. 1a-6, the present application discloses a coherent demodulation utilizing the focusing optical lens 700, and providing the third optical waveguide 204, the fourth optical waveguide 205 and the fifth optical waveguide 206 on the integrated chip 200, the signal demodulation Waveguide MZI 270 and the second balanced optoelectric detector 280 to obtain the round trip time of the laser beam L emitted by the external-cavity tunable laser A to the detection target based on the frequency difference from coherently demodulating, and to further determine the distance from the FMCW lidar to the detection target, realizing frequency-modulated continuous wave (FMCW) coherent laser ranging.

Furthermore, in the present disclosure achieves high-resolution, large solid-state angle scan FMCW ranging in cooperation with a large-angle-range laser beam scan offered by the n free-space optical feedback channels and the dispersive optical element 600.

Seventhly, the present disclosure provides an invention addressing the requirements of lidar in high-end Autonomous Driving and 3D sensing applications etc., and offering the advantages of excellent performance, high reliability, better eye safety and lower cost.

### BRIEF DESCRIPTION OF DRAWINGS

The present disclosure is further illustrated in detail in combination with the drawings and the detailed embodiments.

FIG. 1a is a schematic of one embodiment of an FMCW lidar according to the present disclosure;

FIG. 1b is a schematic of a spectrum of a light intensity of a filtered light through a tunable waveguide filter 230 according to the present disclosure;

FIG. 1c is a schematic of a transmission spectrum of a light intensity of a transmission light of the tunable waveguide filter 230 according to the present disclosure;

FIG. 1d is a schematic of a reflection spectrum of an optical filtering feedback device 230 according to the present disclosure;

FIG. 1e is a schematic of a spectrum of a composite filtering feedback consisting of the tunable waveguide filter 230 and an optical filtering feedback device 400 according to the present disclosure;

FIG. 2a is a schematic of the FMCW lidar shown in FIG. 1a when a planar waveguide optical switch 501 is used to cover n free-space optical feedback channels, and a free-space optical feedback channel 401 is selected to emit the laser light;

FIG. 2b is a schematic structural diagram of the FMCW lidar shown in FIG. 1a when a planar waveguide optical switch 501 is used to cover n free-space optical feedback channels, and a free-space optical feedback channel 40n is selected to emit the laser light;

FIG. 2c is a schematic of a spectrum of a composite filtering feedback consisting of the tunable waveguide filter 230 and the optical filtering feedback devices 400 of the n free-space optical feedback channels together according to the present disclosure;

FIG. 3a is a schematic of the FMCW lidar shown in FIG. 1a when a free-space optical switch 502 is used to cover n free-space optical feedback channels, and a free-space optical feedback channel 401 is selected to emit the laser light;

FIG. 3b is a schematic of the FMCW lidar shown in FIG. 1a when a free-space optical switch 502 is used to cover n free-space optical feedback channels, and a free-space optical feedback channel 40n is selected to emit the laser light;

FIG. 4a is a schematic of the FMCW lidar shown in FIG. 1a when a micro-electromechanical (MEMs) mirror 503 is used to cover n free-space optical feedback channels, and a free-space optical feedback channel 401 is selected to emit the laser light;

FIG. 4b is a schematic structural diagram of the FMCW lidar shown in FIG. 1a when a micro-electromechanical (MEMs) mirror 503 is used to cover n free-space optical feedback channels, and a free-space optical feedback channel 40n is selected to emit the laser light;

FIG. 5 is a structural schematic of the present disclosure using a broadband waveguide loop mirror 240 as the broadband optical feedback structure 210;

FIG. 6 is a schematic structural diagram of a second embodiment of an FMCW lidar according to the present disclosure;

FIG. 7a is a structural schematic wherein light emitted from a light-emission gain chip 100 is coupled to an integrated chip 200 through waveguide butt-coupling according to the present disclosure;

FIG. 7b is a schematic wherein light emitted from the light-emission gain chip 100 is coupled to the integrated chip 200 by evanescent wave coupling according to the present disclosure;

FIG. 8a is a schematic of an optical filtering feedback device 400 composed of a thin-film optical channel transmission filter 410 and a thin-film optical broadband reflection filter 420 according to the present disclosure; and

FIG. 8b is a schematic of a spectrum characteristic of the thin-film optical channel transmission filter 410 and the thin-film optical broadband reflection filter 420 according to the present disclosure.

In the drawings:
external-cavity tunable laser A; output laser beam L; light-emission gain chip 100, left facet 100a of the light-emission gain chip, right facet 100b of the light-emission gain chip, optical waveguide 101 of the light-emission gain chip; integrated chip 200, first facet 200a of the integrated chip, second facet 200b of the integrated chip, groove 200c, first optical waveguide 201, second optical waveguide 202, branch optical waveguide 203, third optical waveguide 204, fourth optical waveguide 205 fifth optical waveguide 206; broadband optical feedback structure 210, second collimating optical lens 211; waveguide phase control section 220; tunable waveguide filter 230, transmission peak 230a, reflected transmission peak 230a′, and Free Spectral Range FSR; broadband waveguide loop mirror 240; on-chip monitoring delay-line Waveguide MZI 250, 1×2 waveguide coupler 251, first waveguide arm 252, second waveguide arm 253, first 2×2 waveguide coupler 254; first balanced optoelectric detector 260, two optical detectors 260a and 260b of the first balanced optoelectric detector; signal demodulation Waveguide MZI 270, second 2×2 waveguide coupler 271, third waveguide arm 272, fourth waveguide arm 273, third 2×2 waveguide coupler 274; second balanced optoelectric detector 280, two optical detectors 280a and 280b of the second balanced optoelectric detector; collimating optical lens 300; optical filtering feedback device 400, reflection band 400a, central wavelength λ of the reflection band, reflection wavelength bandwidth FB of the reflection band, first to nth free-space optical feedback devices 401, . . . , 40n, reflection bands 400a1, . . . , 400an of n optical filtering feedback devices corresponding to the n free-space optical feedback channels, central wavelengths λ₁, . . . , λₙ of the reflection bands of the n optical filtering feedback devices, reflection wavelength bandwidths FB1, . . . , FBn of the n optical filtering feedback devices; thin-film optical channel transmission filter 410, spectrum characteristic 410A of the thin-film optical channel transmission filter, transmission wavelength bandwidth TB of the transmission band, thin-film optical broadband reflection filter 420, spectrum characteristic 420A of the thin-film optical broadband reflection filter; planar waveguide optical switch 501, free-space optical switch 502, micro-electromechanical mirror 503; dispersive optical element 600; focusing optical lens 700.

### DETAILED DESCRIPTION OF THE INVENTION

The present disclosure will be described in detail with reference to the examples and the accompanying drawings so as to facilitate a person skilled in the art to better understand the inventive concept of the present disclosure. However, the scopes of the claims of the present disclosure should not be limited to the examples described below, and it should be understood by a person skilled in the art that other examples obtained without inventive effort without departing from the inventive concept of the present disclosure are also covered by the scope of protection of the present disclosure.

In the description of the present disclosure, it should be clarified that the directional terms “left, right” are only relative concepts in terms of direction, and are intended to facilitate the description or simplification of the present disclosure, rather than indicating or implying specific directions that the present disclosure must have. Therefore, they cannot be understood as limitations on the present disclosure.

The figures of the present disclosure are schematic and do not represent actual dimensions or values.

### Example 1

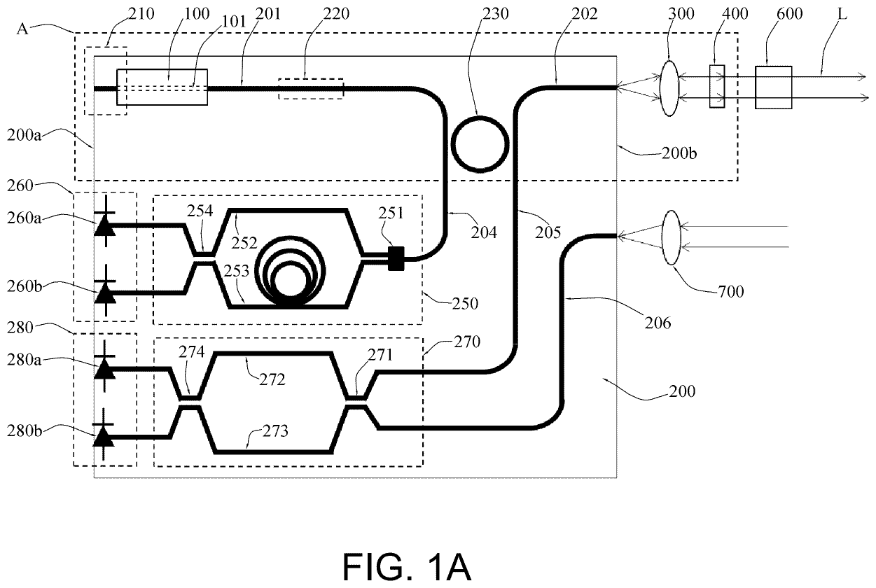

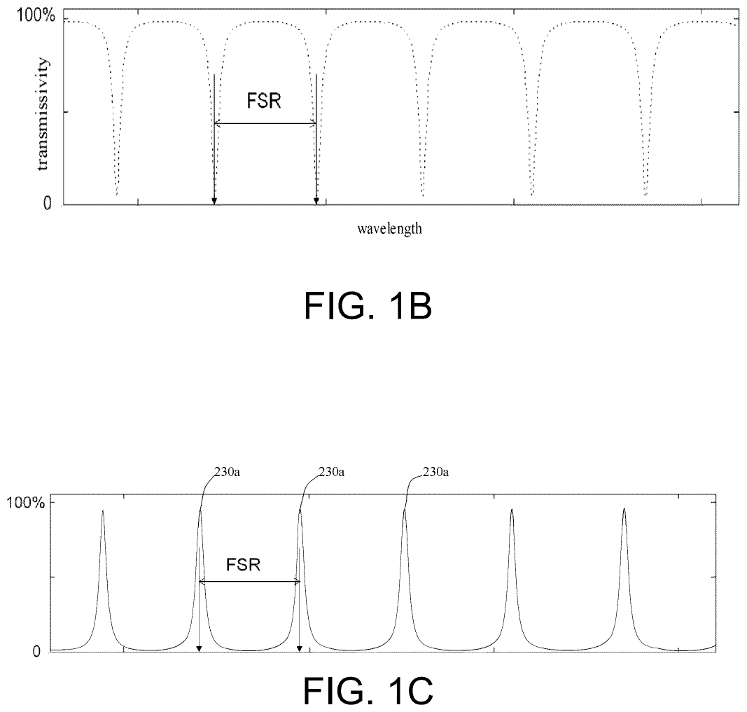

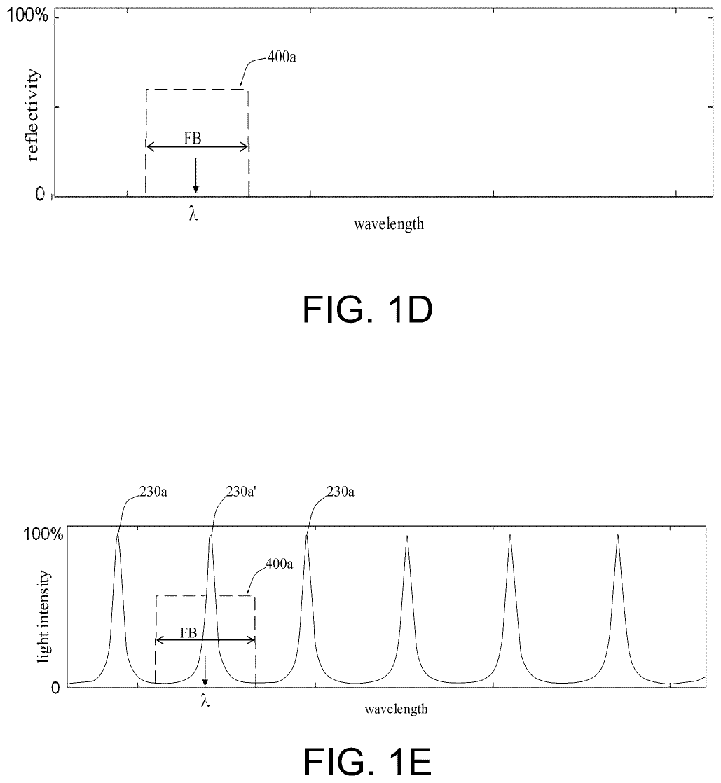

As shown in FIGS. 1a to 8b, the present disclosure discloses an FMCW lidar based on chip integration, characterized by comprising: a light-emission gain chip 100, an integrated chip 200, a collimating optical lens 300 and an optical filtering feedback device 400;
the FMCW lidar constitutes an external-cavity tunable laser of laser light with the following structure that:
the integrated chip 200 is provided with an optical waveguide circuit containing a first optical waveguide 201 and a second optical waveguide 202; two ports of the first optical waveguide 201 are respectively connected to a broadband optical feedback structure 210 and a tunable waveguide filter 230; a first port of the second optical waveguide 202 is connected to the tunable waveguide filter 230, and a second port of the second optical waveguide 202 is configured for emitting light out of the integrated chip 200; and the first optical waveguide 201 or the second optical waveguide 202 passes through a waveguide phase control section 220 (phase control or PC); and
the light-emission gain chip 100 is capable of generating broadband spontaneous photonic emission through a during current injection based on electro-optic conversion through its optical waveguide 101, and light emitted therefrom is coupled to the first optical waveguide 201 or the second optical waveguide 202; and the collimating optical lens 300 and the optical filtering feedback device 400 are sequentially placed on an exit optical path of the second optical waveguide 202.

The present application disclose four scenarios on the location and placement of the waveguide phase control section 220 and the light-emission gain chip 100: the case where the first optical waveguide 201 passes through the waveguide phase control section 220 and the light emitted from the light-emission gain chip 100 is coupled to the first optical waveguide 201, and three cases where “the second optical waveguide 202 passes through the waveguide phase control section 220” and/or “the light emitted from the light-emission gain chip 100 is coupled to the second optical waveguide 202” are not shown in the drawings.

Where:

The broadband optical feedback structure 210 is capable of reflecting light along an original path of an incident direction;
the waveguide phase control section 220 is capable of controlling a round trip optical path of a photon in the external-cavity tunable laser A to be an integer multiple of a wavelength of a laser emitted by the external-cavity tunable laser A, and the optical round trip constitutes: photons traveling from the broadband optical feedback structure 210, to the optical waveguide 101 of the light-emission gain chip 100, the first optical waveguide 201 and the waveguide phase control section 220, the tunable waveguide filter 230, the second optical waveguide 202, the collimating optical lens 300, the optical filtering feedback device 400, being reflected at the broadband optical feedback structure 210 and traveling back along the original optical path of to the broadband optical feedback structure 210 in a reverse direction;
the tunable waveguide filter 230 has the following characteristics that: light coupled to the second optical waveguide 202 by the first optical waveguide 201 being filtered by the tunable waveguide filter 230 and light coupled to the first optical waveguide 201 by the second optical waveguide 202 being filtered by the tunable waveguide filter 230 are both denoted as transmission light; a light intensity of the transmission light has a transmission spectrum composed of several comb-like transmission peaks 230a as shown in FIG. 1c, and an interval between peak wavelengths of any two adjacent transmission peaks 230a is a fixed Free Spectral Range (FSR); and the tunable waveguide filter 230 is capable of simultaneously tuning the peak wavelengths of all the transmission peaks 230a, i.e., translating the transmission spectrum shown in FIG. 1c along the wavelength axis; and
the optical filtering feedback device 400 is capable of reflecting light of wavelength within a reflection band 400a along the original path of the incident direction, with reference to FIG. 1d, the reflection band 400a having a fixed central wavelength λ and a reflection wavelength bandwidth FB of the reflection band 400a smaller than, preferably close to, the Free Spectral Range (FSR). In this way, the wavelength of the transmission peak 230a falling in the reflection band 400a is chosen to be lasing wavelength.

Thus, taking the case of the first optical waveguide 201 passing through the waveguide phase control section 220 and the light emitted by the light-emission gain chip 100 being coupled into the first optical waveguide 201 via the optical waveguide 101 thereof as an example, the operation principle of the external-cavity tunable laser A of the present disclosure is described as follows.

Firstly, the light-emission gain chip 100 serves as a photon source and a laser amplification source for the external-cavity tunable laser A, and the light emitted by the light-emission gain chip 100 via the optical waveguide 101 thereof is coupled into the first optical waveguide 201 of the integrated chip 200, and is split into left-propagating light and right-propagating light according to their propagation direction, and when the left-propagating light in the first optical waveguide 201 reaches the broadband optical feedback structure 210, it is reflected along the original path and is coupled back to the optical waveguide 101 of the light-emission gain chip 100, and then propagates right to be coupled into the first optical waveguide 201 to become right-propagating light; after passing through the waveguide phase control section 220, the right-propagating light in the first optical waveguide 201 is filtered by the tunable waveguide filter 230 to become a transmission light having a transmission spectrum as shown in FIG. 1c and coupled to the second optical waveguide 202; and transmission light in the second optical waveguide 202 emits from the second port of the second optical waveguide 202 out of the integrated chip 200, and is incident on the optical filtering feedback device 400 after being collimated by the collimating optical lens 300.

Then, with reference to FIG. 1e, among the transmission light incident on the optical filtering feedback device 400, the transmission peak within in the reflection band 400a of the optical filtering feedback device 400, i.e., the transmission peak 230a′ as shown in FIG. 1c, would be reflected by the optical filtering feedback device 400 at certain reflectivity thereof in the original path, so as to be coupled back to the optical waveguide 101 of the light-emission gain chip 100 along the path of the optical filtering feedback device 400, the collimating optical lens 300, the second optical waveguide 202, the tunable waveguide filter 230, the first optical waveguide 201 and the waveguide phase control section 220, and then propagates left to be coupled to and incident on the broadband optical feedback structure 210, and then reflected back to the first optical waveguide 201 from the broadband optical feedback structure 210 to propagate right direction so as to continuously repeat the above-mentioned process together with the light coupled into the first optical waveguide 201 from the optical waveguide 101 of the light-emission gain chip 100, so that photons are resonantly amplified between the broadband optical feedback structure 210 of the external-cavity tunable laser A and the optical filtering feedback device 400, thereby achieving amplification of light at the wavelength of the reflected transmission peak 230a′ in the external-cavity tunable laser A, and forming a laser beam L emitted by the external-cavity tunable laser A.

In such process, the peak wavelength of the transmission peak 230a′ is the wavelength of the laser beam L, and the wavelength tuning is performed by controlling the tunable waveguide filter 230, i.e., tuning simultaneously the wavelength of all the transmission peaks 230a in the transmission spectrum shown in FIG. 1c, so that the peak wavelength of the reflected transmission peak 230a′ changes within the reflection band 400a, i.e. the wavelength of the laser beam L can be correspondingly tuned, thereby achieving the rapid wavelength tuning of the laser beam L output by the external-cavity tunable laser A within the reflection band 400a range of the optical filtering feedback device 400, and the external-cavity tunable laser A offers a simple, reliable and rapid laser beam L wavelength tuning mechanism.

Furthermore, since the wavelength bandwidth FB of the reflection band 400a is less than the Free Spectral Range FSR, only one peak is selected to ensure a single-mode tuning frequency selection of the laser beam L output by the external-cavity tunable laser A. Besides, in the optical communication band of 1550 nm, since the Free Spectral Range (FSR) of the tunable waveguide filter 230 can be 10+ nm or even a few tens of nanometers, the external-cavity tunable laser A can achieve a continuous wavelength tuning of 10+ nm or even a few tens of nanometers, and cover a tuning range up to 100 nanometers.

In addition, for the three cases of alternatively “the second optical waveguide passing through the waveguide phase control section” and/or “the light emitted from the light-emission gain chip being coupled to the second optical waveguide”, the operation principle is the same as that described above, and the description thereof will not be repeated.

The Example 1 mentioned above represents a basic implementation, it can be further optimized, improved and defined:

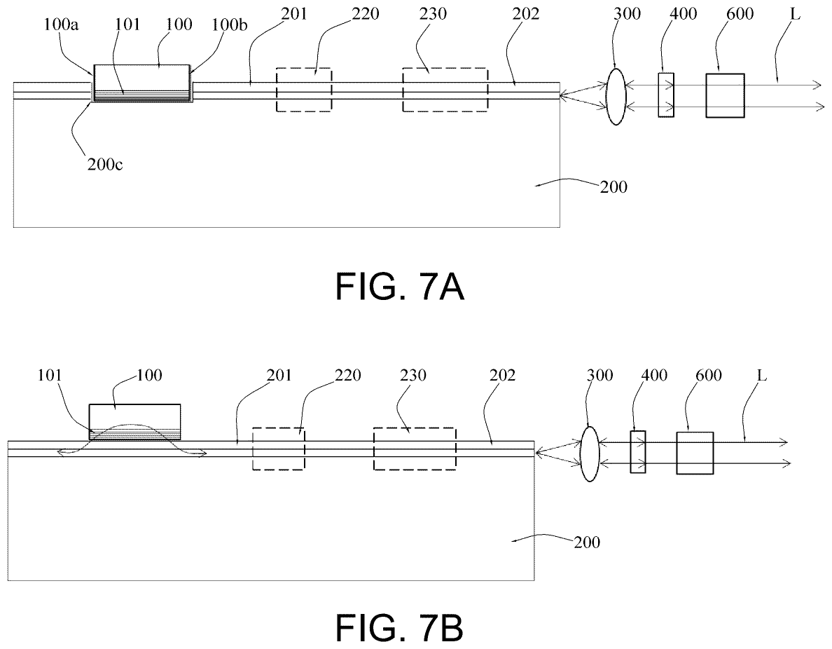

As one preferred way of coupling the light emitted from the light-emission gain chip 100 into the optical waveguide of the integrated chip 200, as shown in FIG. 7a, light emitted by the light-emission gain chip 100 is coupled into the optical waveguide of the integrated chip 200 via the optical waveguide 101 thereof by means of waveguide butt-coupling, i.e., the integrated chip 200 is provided with a etched trench 200c, the light-emission gain chip 100 is flip-chip bonded in the trench 200c, and a right facet 100b of the light-emission gain chip 100 is coated with an optical anti-reflection film; and an facet of the first optical waveguide 201 or the second optical waveguide 202 is coated with an optical anti-reflection film and extends to the groove 200c so as to be butt-coupled with the optical waveguide 101 of the light-emission gain chip 100 at the right facet 100b of the light-emission gain chip 100, and a left facet 100a of the light-emission gain chip 100 is coated with a reflection film having a reflectivity higher than a predetermined value as another feedback mirror of the external-cavity tunable laser A, so that light emitted from the light-emission gain chip 100 is coupled into the first optical waveguide 201 or the second optical waveguide 202 by means of optical mode overlap.

As a second preferable way of coupling the light emitted from the light-emission gain chip 100 into the optical waveguide of the integrated chip 200, as shown in FIG. 7b, light emitted from the light-emission gain chip 100 is coupled into the optical waveguide of the integrated chip 200 through evanescent wave coupling via the optical waveguide 101 thereof, i.e., the light-emission gain chip 100 is flip-chip mounted on a surface of the integrated chip 200, and the optical waveguide 101 of the light-emission gain chip 100 is in a close contact to the first optical waveguide 201 or the second optical waveguide 202, so that light emitted by the light-emission gain chip 100 is coupled into the first optical waveguide 201 or the second optical waveguide 202 through an optical evanescent wave coupling.

The light-emission gain chip 100 can be a III-V compound semiconductor active gain chip or a photonic source chip, and the III-V compound semiconductor active gain chip is composed of common compound semiconductor materials, such as III-V group InP series.

The integrated chip 200 can be a silicon optical integrated chip or a passive photonic integrated chip.

Preferably, the second facet 200b of the integrated chip 200 is coated with a broadband optical anti-reflection coating.

The waveguide phase control section 220 controls the round trip optical path of the photon in the external-cavity tunable laser A to be an integral multiple of a wavelength of the laser beam L emitted by the external-cavity tunable laser A in such a manner that can be but not limited to the cases where the integrated chip 200 has a first metal electrode near the waveguide phase control section 220, and the first metal electrode changes an optical refractive index of a corresponding optical waveguide constituting the waveguide phase control section 220 through a thermo-optic effect or an electro-optic effect so as to change a phase of light transmitting through the waveguide phase control section 220, ensuring that the round trip optical path is an integral multiple of the wavelength of the laser beam L. The thermo-optic effect is that heating by the first metal electrode changes the temperature of the corresponding waveguide, that changes the refractive index of the waveguide through temperature dependence of refractive index. The electro-optic effect is that changing of the current on the first metal electrode changes the refractive index of the waveguide through the carrier density effect on refractive index.

The tunable waveguide filter 230 tunes simultaneously the peak wavelengths of all transmission peaks 230a, the way to shift the transmission spectrum along the wavelength as shown in FIG. 1c can be, but is not limited to, that the integrated chip 200 has a second metal electrode near the tunable waveguide filter 230, and the second metal electrode changes an optical refractive index of a corresponding optical waveguide constituting the tunable waveguide filter 230 through a thermo-optic effect or an electro-optic effect so as to change a resonance frequency of the tunable waveguide filter 230 to achieve wavelength tuning of the laser beam L. The thermo-optic effect is that heating by the second metal electrode changes the temperature of the corresponding waveguide, that changes the refractive index of the waveguide through temperature dependence of refractive index. The electro-optic effect is that changing of the current on the second metal electrode changes the refractive index of the waveguide through the carrier density effect on refractive index.

The tunable waveguide filter 230 may be, but is not limited to: any one of integrated photonic devices such as a tunable waveguide ring resonator, a tunable sampled grating, a tunable waveguide Bragg grating, a tunable waveguide transmission grating with periodic transmission peaks, a tunable super-structure grating, and a series of tunable waveguide MZI interferometers and a tunable waveguide ring resonator is preferably used in the embodiment of the present disclosure as shown in the drawings.

The optical filtering feedback device 400 can be, but is not limited to, any one of, or any combination of multiple of, a thin-film optical reflection filter, a broadband diffraction grating, and an optical meta-surface device.

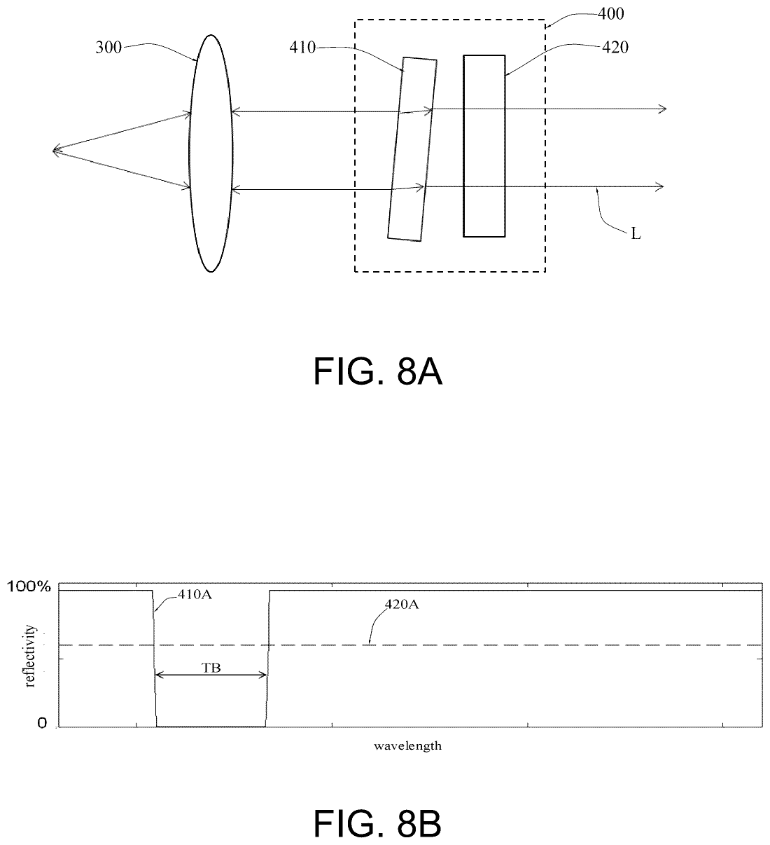

With reference to FIG. 8a and FIG. 8b, the optical filtering feedback device 400 is composed of a thin-film optical channel transmission filter 410 and a thin-film optical broadband reflection filter 420, and the thin-film optical channel transmission filter 410 and the thin-film optical broadband reflection filter 420 are sequentially placed on an exit optical path of the collimating optical lens 300, an optical axis of the thin-film optical channel transmission filter 410 has an certain incident angle with respect to an optical axis of the collimating optical lens 300, and the optical axis of the thin-film optical broadband reflection filter 420 is coaxial with the optical axis of the collimating optical lens 300;

With reference to FIG. 8b, the thin-film optical channel transmission filter 410 has the spectrum characteristic 410A shown in the figure, i.e., it only transmits light within a transmission band, the transmission band has a fixed central wavelength, and the transmission wavelength bandwidth TB of the transmission band is less than and preferably close to the Free Spectral Range FSR, so as to ensure the single-mode frequency selection of the external-cavity tunable laser A; and
with reference to FIG. 8b, the thin-film optical broadband reflection filter 420 has the spectral characteristics 420A shown in the figure, i.e. it is capable of reflecting light along an original path of an incident direction with a certain reflectivity.

Thus, the light incident on the optical filtering feedback device 400 via the collimating optical lens 300 is divided into reflected light reflected by the thin-film optical channel transmission filter 410 and transmission light transmitting through the thin-film optical channel transmission filter 410; due to the inclined arrangement of the thin-film optical channel transmission filter 410, the reflected light cannot be coupled back to the second optical waveguide 202 through the collimating optical lens 300, while the transmission light can be coupled back to the second optical waveguide 202 via the thin-film optical channel transmission filter 410 and the collimating optical lens 300 after being reflected at the thin-film optical broadband reflection filter 420, and it is achieved that the optical filtering feedback device 400 reflects the light of wavelength within the reflection band 400a shown in FIG. 1d along the original path of the incident direction.

In addition, in the present disclosure, all other optical elements or functions, except these provided in free-space, are implemented on the integrated chip 200, such as the transmission optical waveguide, the waveguide phase control section 220, the tunable waveguide filter 230, the MZI waveguide interferometer, the metal electrode, the waveguide optical delay loop, the balanced optoelectric detector, etc. can be monolithically integrated on the integrated chip 200.

### Example 2

On the basis of the Example 1 mentioned above, Example 2 discloses additionaly the following preferred implementations.

As one of preferred way for laser beam L to exit in the present disclosure: as shown in FIGS. 1a to 5, the external-cavity tunable laser A emits the laser beam L through the optical filtering feedback device 400 in the manner that the broadband optical feedback structure 210 is a high-reflectivity broadband optical feedback structure with a reflectivity higher than a preset value, so that as much light incident on the broadband optical feedback structure 210 is reflected along the original path of the incident direction as possible; and the reflectivity of the optical filtering feedback device 400 is lower than the preset value, so that the light incident on the optical filtering feedback device 400 with wavelength within the reflection band 400a is divided into two parts, one part is reflected along the original path of the incident direction and participates in the amplification of the reflected transmission peak 230a′ in the external-cavity tunable laser A, and the other part is transmitted through the optical filtering feedback device 400 and exits as a laser beam L.

For example, the reflectivity of the broadband optical feedback structure 210 may be above 99% and the reflectivity of the optical filtering feedback device 400 may be 50%, whereby photons in the external-cavity tunable laser A are resonantly amplified by reflection between the optical filtering feedback device 400 and the broadband optical feedback structure 210, and 50% of the photons may pass through the optical filtering feedback device 400 and exit as a laser beam L.

The basic implementation of Example 2 mentioned above represents one of the basic implementations, it can be further optimized, improved and defined.

Preferably, as one preferred high-reflectivity broadband optical feedback structure, as shown in FIG. 1a, the high-reflectivity broadband optical feedback structure as the broadband optical feedback structure 210 includes that an end portion of the first optical waveguide 201 terminates at a first facet 200a of the integrated chip 200, and the first facet 200a of the integrated chip 200 is coated with a broadband high-reflection film having a reflectivity higher than the preset value, such that light incident on the broadband optical feedback structure 210 is reflected in the original path at the broadband high-reflection film.

Preferably, as a second preferred configuration with high-reflectivity broadband optical feedback, as shown in FIG. 7a, configuration with the high-reflectivity broadband optical feedback structure as the broadband optical feedback 210 includes that the optical waveguide 101 emitting light from the light-emission gain chip 100 is butt-coupled to an facet of the first optical waveguide 201 or the second optical waveguide 202 at a right facet 100b of the light-emission gain chip 100, such that the light emit by the light-emission gain chip 100 is coupled to the first optical waveguide 201 or the second optical waveguide 202; and a left facet 100a of the light-emission gain chip 100 is coated with a broadband high-reflection film having a reflectivity higher than the preset value, such that light incident on the broadband optical feedback structure 210 is reflected in the original path at the broadband high-reflection film, and returns along the original path of the optical waveguide 101 of the light-emission gain chip 100.

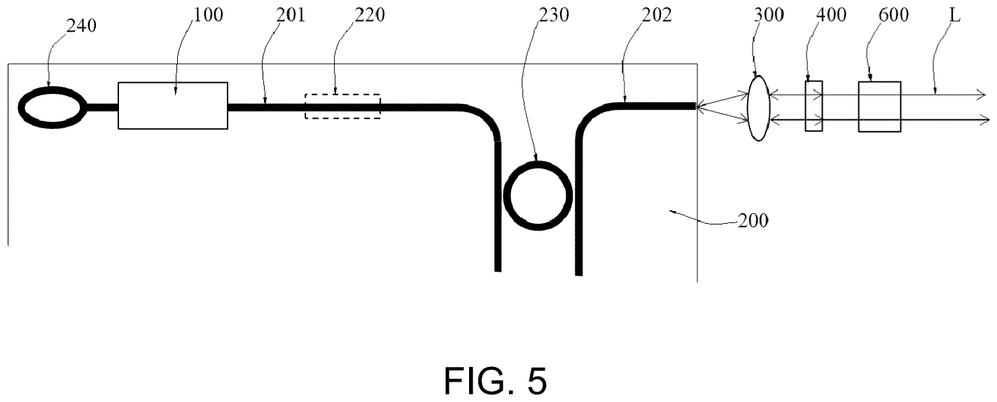

Preferably, as a third preferred configuration with high-reflectivity broadband optical feedback structure, as shown in FIG. 5, configuration with a high-reflectivity broadband optical feedback structure as the broadband optical feedback structure 210 includes: a broadband waveguide loop mirror 240 on the integrated chip 200; and the optical waveguide 101 of the light-emission gain chip 100 and the first optical waveguide 201 are coupled and inbetween the broadband waveguide loop mirror 240 and the tunable waveguide filter 230.

As another preferred implementation of the present disclosure, as shown in FIG. 1a, the FMCW lidar further includes a dispersive optical element 600; and the dispersive optical element 600 is placed on an exit optical path of an output laser beam L of the external-cavity tunable laser A.

For example, for the FMCW lidar shown in FIG. 1a, the laser beam L of the external-cavity tunable laser A exits through the optical filtering feedback device 400, and the dispersive optical element 600 is disposed in the exit path of the optical filtering feedback device 400.

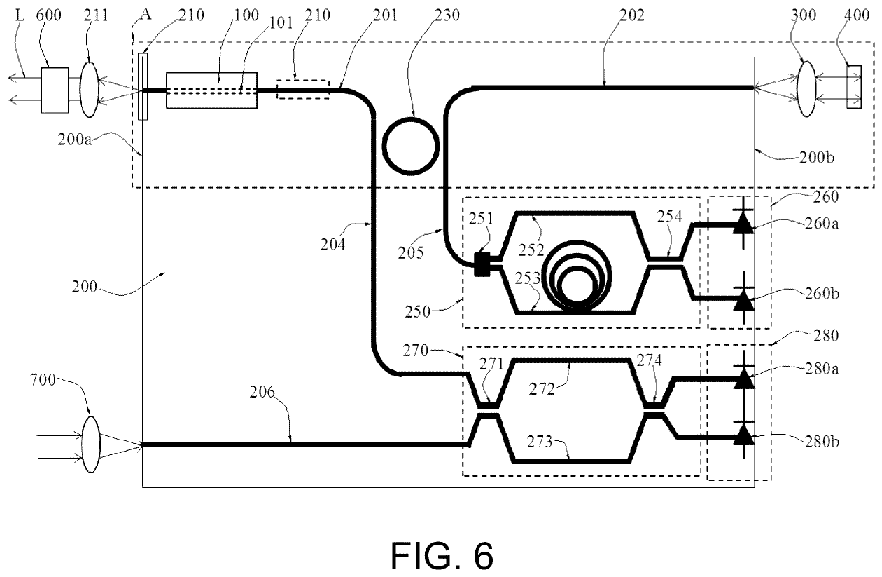

As another example, for the FMCW lidar shown in FIG. 6, the laser beam L of the external-cavity tunable laser A exits through the broadband optical feedback structure 210 and the second collimating optical lens 211, and then the dispersive optical element 600 placed on the exit optical path.

In the present disclosure, the provided dispersive optical element 600 operates as follows.

The laser beam L output by the external-cavity tunable laser A exits through the dispersive optical element 600, and since the exit angle of the dispersive optical element 600 changes correspondingly with the wavelength tuning of the incident laser light, when the laser beam L is tuned in wavelength within the reflection band 400a range of the optical filtering feedback device 400 through the tunable waveguide filter 230, the exit angle of the laser beam L exiting through the dispersive optical element 600 changes corresponding to the wavelength tuning, so that without mechanical movement of any kind, a solid angular scanning of laser beam driven by wavelength tuning is achieved.

The dispersive optical element 600 can be, but is not limited to any one of, or any combination of multiple of, a diffraction grating, a diffractive optical element (DOE), a holographic optical element (HOW), and an optical meta-surface device.

### Example 3

On the basis of the Example 2 above-mentioned, Example 3 discloses additionally the following preferred implementations.

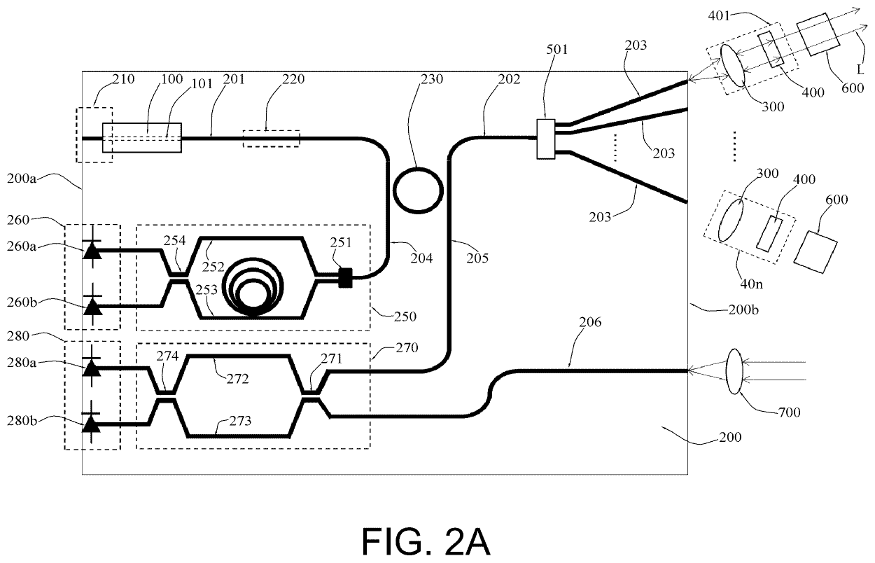

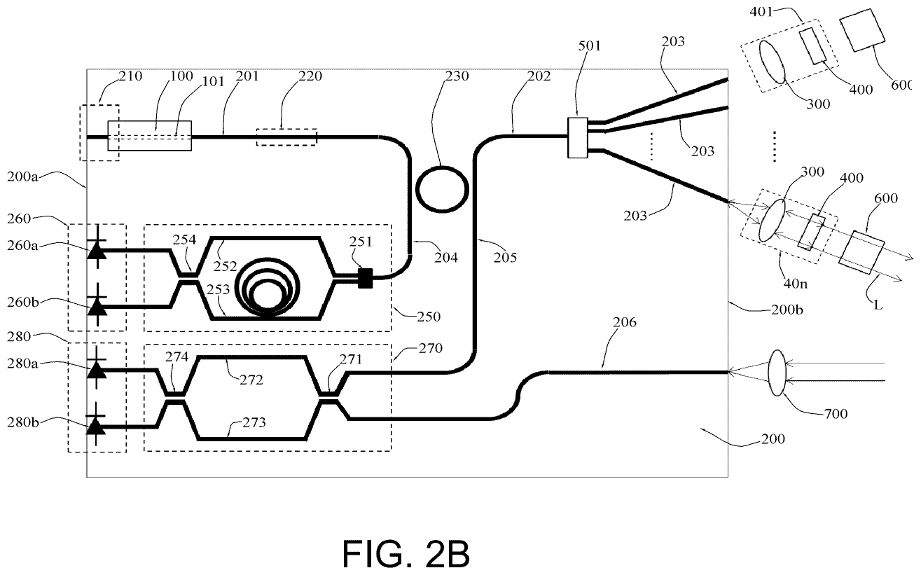

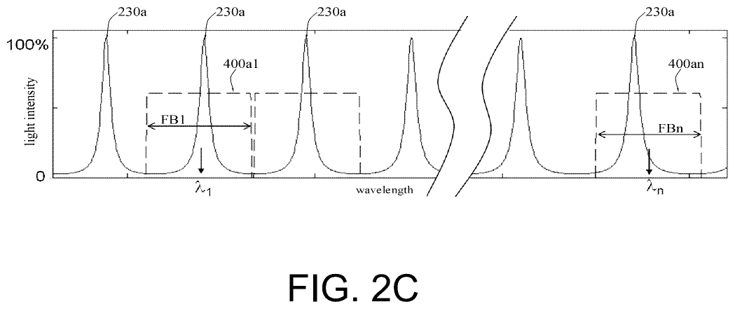

As shown in FIGS. 2a-4b, the FMCW lidar is provided with an optical switch and n free-space optical feedback channels, n≥2; in the figure, the first to the nth free-space optical feedback channel are successively denoted as 401, . . . , 40n; and the optical switch should have a large operation wavelength bandwidth.

Each of the free-space optical feedback channels is provided with an optical filtering feedback device 400, and for n optical filtering feedback devices 400 and n free-space optical feedback channels 401, . . . , 40n, exit directions of optical paths of the n optical filtering feedback devices 400 are different from each other, the central wavelengths λ of the reflection bands of the n optical filtering feedback devices 400 are different from each other as well and wavelength separation therebetween are integer multiples of the Free Spectral Range (FSR), while the reflection bands 400a of the n optical filtering feedback devices 400 do not overlap each other, and the reflection wavelength bandwidths FB of the n optical filtering feedback devices 400 can be the same or different; for example, with reference to FIG. 2c, n optical filtering feedback devices 400 in correspondence with n free-space optical feedback channels 401, . . . , 40n have sequentially the reflection bands 400a1, . . . , 400an, central wavelengths of reflection band λ₁, . . . , λₙ, and reflection wavelength bandwidths FB1, . . . , FBn etc.

The optical switch is able to select any one of the n free-space optical feedback channels 401, . . . , 40n for optical coupling with the second optical waveguide 202 such that each free-space optical feedback channel can form one exit optical path of the second optical waveguide 202.

Thus, the present disclosure provides an optical switch and n free-space optical feedback channels that operate in a principle as follows.

With reference to FIGS. 1c and 2c, as previously stated, the light is filtered by the tunable waveguide filter 230 into a transmission light with a transmission spectrum as shown in FIG. 1c and coupled to the second optical waveguide 202, and propagates out of the integrated chip 200 via the second port of the second optical waveguide 202; by means of the optical switch, the free-space optical feedback channel coupled to the second optical waveguide 202 is selected, enabling the transmission light mentioned above to be incident on the optical filtering feedback device 400 of the corresponding free-space optical feedback channels 401, . . . , 40n, whereby, with the optical filtering feedback device 400 selected by the optical switch, part of the light having a transmission light wavelength within the reflection band 400a of the selected optical filtering feedback device 400 is reflected in the original path, and the remaining light transmits through the selected optical filtering feedback device 400 to output as the laser beam L; for example, the optical switch can select the optical filtering feedback device 400 corresponding to the reflection band 400a1 (or the reflection band 400an) to reflect and exit the transmission peaks 230a of the transmission light within the reflection band 400a1 (or the reflection band 400an) in the original path; and, therefore, the n different optical filtering feedback can be selected respectively from n free-space optical feedback channels with the optical switch, so that the laser beam L output by the external-cavity tunable laser A can exit correspondingly at n different directions, and the wavelength tuning of the laser beam output L by the external-cavity tunable laser A in the corresponding n different reflection band wavelength 400a ranges can be achieved, so as to achieve the wavelength tuning of the external-cavity tunable laser A for more wavelength regions and a wider wavelength range and more choices of the exit directions.

The basic implementation represented by Example 3 mentioned above can be further optimized, improved, and defined.

Preferably, as shown in FIGS. 1c to 1e and FIG. 2c, the central wavelength separation between any two adjacent reflection bands in the n optical filtering feedback devices 400 is the Free Spectral Range FSR; and the reflection bands 400a of the n optical filtering feedbacks 400 have a reflection wavelength bandwidth FB smaller than and close to the Free Spectral Range FSR, and the central wavelength separation between any two adjacent reflection bands 400a is smaller than a preset value, so that the reflection bands 400a of the n optical filtering feedback devices 400 are close to the approximately continuous spectrum shown in FIG. 2c. Thus, since the Free Spectral Range FSR of the tunable waveguide filter 230 can be as much as 10+ or even few tens of nanometers, by switching and adding-up transition the reflection bands 400a of the n optical filtering feedback devices 400, it is possible to tune the external-cavity tunable laser A over a wavelength range of a hundred nm or even more.

As one of the preferred implementations to provide n free-space optical feedback channels, as shown in FIGS. 2a and 2b, the optical switch is a planar waveguide optical switch 501 on the integrated chip 200; n branch optical waveguides 203 are provided on the integrated chip 200 corresponding to the n free-space optical feedback channels 401, . . . , 40n; and the second port of the second optical waveguide 202 is connected to a main port of the planar waveguide optical switch 501, n branch ports of the planar waveguide optical switch 501 are respectively connected to the n branch optical waveguides 203, and the other end of the n branch optical waveguides 203 terminates at second facet 200b of the integrated chip 200; and
each of the free-space optical feedback channels is provided with an collimating optical lens 300 and an optical filtering feedback device 400; and the collimating optical lens 300 and the optical filtering feedback device 400 are sequentially placed on an exit optical path corresponding to the branch optical waveguide 203.

Thus, by selecting different branch optical waveguides 203 with the planar waveguide optical switch 501, different external-cavity tunable lasers A can be constructed; for example, when the branch optical waveguide 203 corresponding to the free-space optical feedback channel 401 is selected, the external-cavity tunable laser A is composed of a hybrid combination of the broadband optical feedback structure 210, the light-emission gain chip 100 and the optical waveguide 101 thereof, the first optical waveguide 201 of the integrated chip 200, the waveguide phase control section 220, the tunable waveguide filter 230, the second optical waveguide 202, the planar waveguide optical switch 501, the branch optical waveguide 203 corresponding to the free-space optical feedback channel 401, the collimating optical lens 300 corresponding to the free-space optical feedback channel 401 and the optical filtering feedback device 400; when the branch optical waveguide 203 corresponding to the free-space optical feedback channel 40n is selected, the external-cavity tunable laser A is composed of a hybrid integration of the broadband optical feedback structure 210, the light-emission gain chip 100 and the optical waveguide 101 thereof, the first optical waveguide 201 of the integrated chip 200, the waveguide phase control section 220, the tunable waveguide filter 230, the second optical waveguide 202, the planar waveguide optical switch 501, the branch optical waveguide 203 corresponding to the free-space optical feedback channel 40n, the collimating optical lens 300 corresponding to the free-space optical feedback channel 40n and the optical filtering feedback device 400.

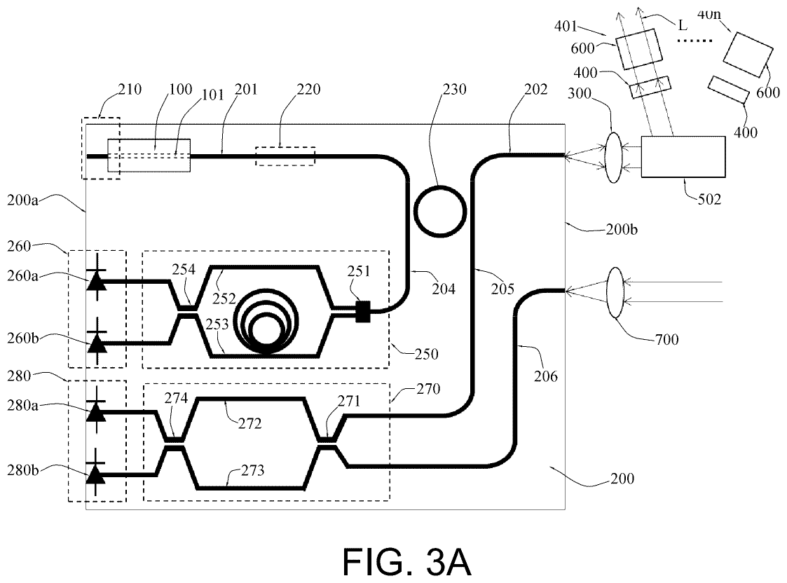

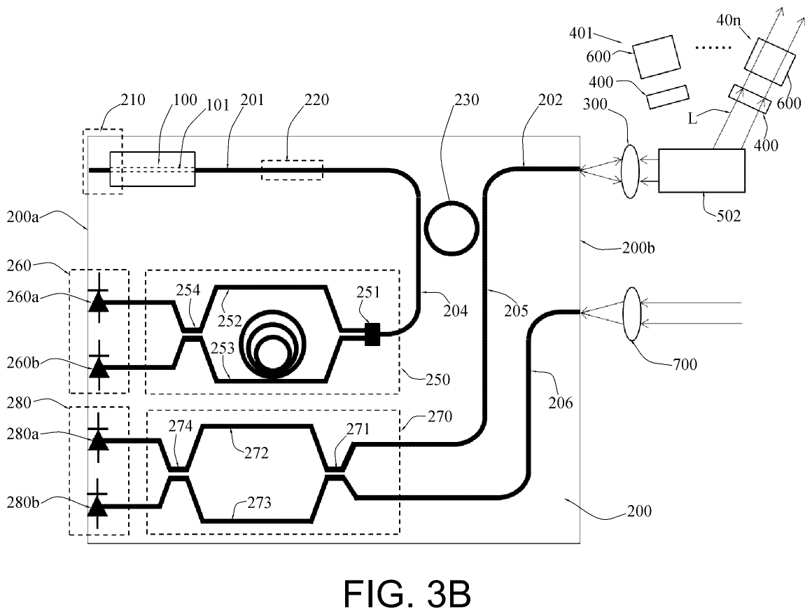

As a second preferred implementation to provide n free-space optical feedback channels, as shown in FIGS. 3a and 3b, the optical switch is a free-space optical switch 502, and the free-space optical switch 502 has one main optical port and n branch optical ports in correspondence to the n free-space optical feedback channels respectively; and the n free-space optical feedback channels share one single collimating optical lens 300, and each of the free-space optical feedback channels is provided with an optical filtering feedback device 400; and
the second port of the second optical waveguide 202 terminates at a second facet 200b of the integrated chip 200, the collimating optical lens 300 and the main optical port of the free-space optical switch 502 are placed sequentially on the exit optical path of the second optical waveguide 202, and the n branch optical ports of the free-space optical switch 502 are aligned respectively to the incident optical paths of the optical filtering feedback devices 400 of the n free-space optical feedback channels.

Thus, different external-cavity tunable lasers A can be constructed by selecting different branch optical ports for optical coupling through the main optical port by the free-space optical switch 502.

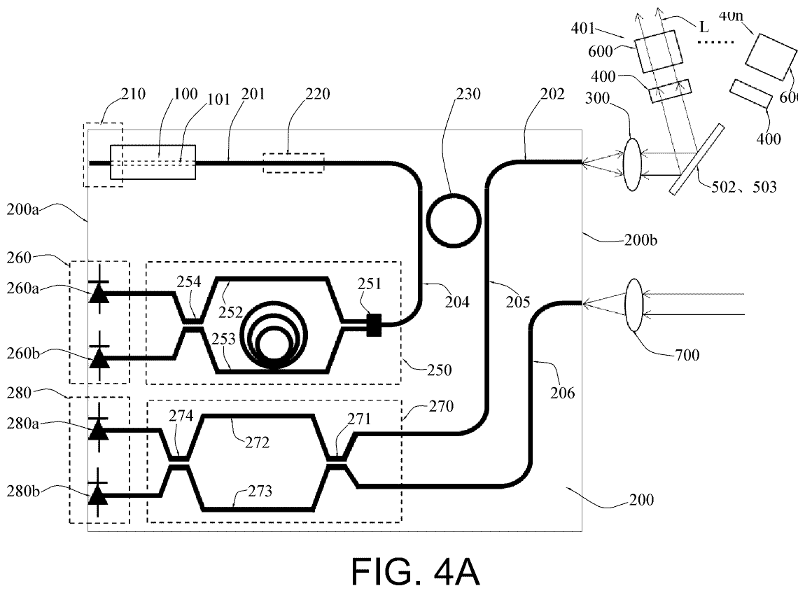

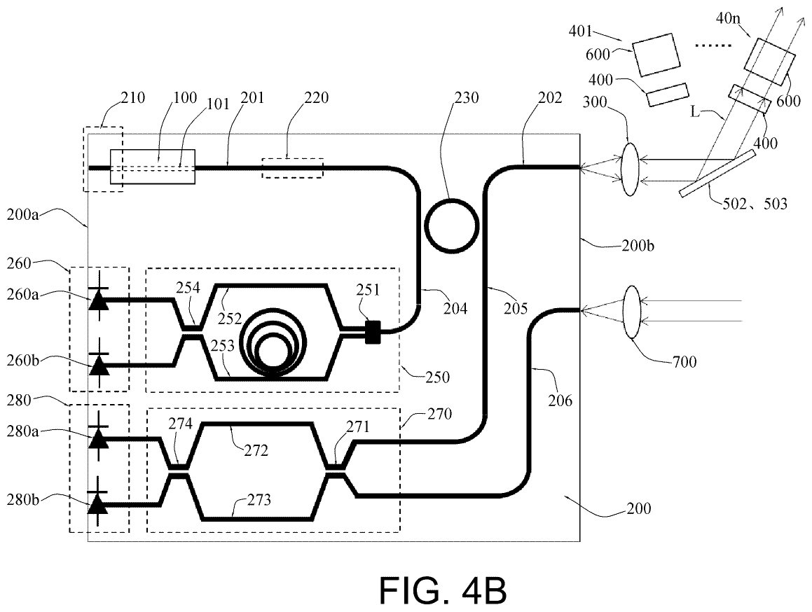

Preferably, as shown in FIGS. 4a and 4b, the free-space optical switch 502 is a micro-electromechanical mirror (MEMs mirror) 503.

The free-space optical switch 502 may not be limited to a MEMs, a liquid crystal optical device, an optical meta-surface device, or a combination of any plurality thereof.

As another preferred implementation of the present disclosure, as shown in FIGS. 2a˜4b, exit directions of the n free-space optical feedback channels 401, . . . , 40n take a fan-out distribution with uniformly spaced angles; and
a dispersive optical element 600 is placed respectively on the exit optical path of the optical filtering feedback device 400 corresponding to each free-space optical feedback channel.

The dispersive optical element 600 can be, but is not limited to any one of, or any combination of multiple of, a diffraction grating, a diffractive optical element (DOE), a holographic optical element (HOW), and an optical meta-surface device.

Thus, the present disclosure provides n free-space optical feedback channels 401, . . . , 40n in combination with the respective dispersive optical element 600, the operating principle of which is as follows.

When the laser beam L of the external-cavity tunable laser A exits through any one of the free-space optical feedback channels, it passes the dispersive optical element 600 on path, and since the exit angle of the dispersive optical element 600 changes correspondingly with the tuning of the wavelength of the incident laser, when the laser beam L is wavelength tuned within the reflection band 400a of the optical filtering feedback device 400 by the tunable waveguide filter 230, the exit angle of the laser beam L after the dispersive optical element 600 changes correspondingly, so that without any mechanical movement, solid-state angular scanning of the laser beam is realized driven by wavelength tuning;

Besides, with the n free-space optical feedback channels 401, . . . , 40n distributed in a fan-out distribution at uniformly spaced angles in, the laser beam will exit in corresponding direction accordingly, a solid-state angular scam of the laser beam can be carried out with the dispersive optical element 600 on each of the free-space optical feedback channel 401, . . . ,40n; and
thus, the present disclosure enables a wide range angular scan of laser detection.

### Example 4

On the basis of any of the Examples 1 to 3 mentioned above, Example 4 discloses additionally the following preferred implementations.

As the second preferred way of exiting the laser beam L in the present disclosure, as shown in FIG. 6, the external-cavity tunable laser A emits the laser beam L through the broadband optical feedback structure 210 in such manner that a reflectivity of the optical filtering feedback device 400 is higher than the preset value, such that as much light incident on the optical filtering feedback device 400 after the collimation of lens 300 is reflected along the original path of the incident direction as possible; the first optical waveguide 201 is terminated at a first facet 200a of the integrated chip 200, and the broadband optical feedback structure 210 is a broadband reflection coated on the first facet 200a with a reflectivity lower than the preset value; and a second collimating optical lens 211 is placed on an exit optical path of the first optical waveguide 201 in order to achieve collimation of the exit laser beam L.

For example, the reflectivity of the above-mentioned optical filtering feedback device 400 can be above 99%, and the reflectivity of the broadband reflection coating as the broadband optical feedback structure 210 can be 50%, whereby photons are reflected and resonantly amplified in the external-cavity between the optical filtering feedback device 400 and the broadband reflection 210, and 50% of the photons may pass through the broadband reflection to emit as the laser beam L.

### Example 5

On the basis of any one of the Examples 1 to 4 mentioned above, the Example 5 discloses additionally the following preferred implementations.

As shown in FIGS. 1a-6, the integrated chip 200 is further provided with a third optical waveguide 204, a fourth optical waveguide 205, an on-chip monitoring delay-line waveguide MZI 250 and a first balanced optoelectric detector 260;
a first port of the third optical waveguide 204 and a first port of the fourth optical waveguide 205 are respectively connected to the tunable waveguide filter 230, and the tunable waveguide filter 230 also has the following characteristics that: light coupled to the third optical waveguide 204 by the first optical waveguide 201 via the tunable waveguide filter 230 and light coupled to the fourth optical waveguide 205 by the second optical waveguide 202 via the tunable waveguide filter 230 are both denoted as filtered light; and a light intensity of the filtered light has a spectrum complementary to the transmission spectrum as shown in FIG. 1b;
as both the second port of the third optical waveguide 204 and the second port of the fourth optical waveguide 205 are out-coupling port of the external-cavity tunable laser A, the light exiting from them is the laser light generated by the external-cavity tunable laser A;
laser light exiting any one of a second port of the third optical waveguide 204 and a second port of the fourth optical waveguide 205 is transmitted to the first balanced optoelectric detector 260 through the on-chip monitoring delay-line waveguide MZI 250; among them, FIG. 1a, FIG. 2a to FIG. 4b show a case where light from the second port of the third optical waveguide 204 enters the on-chip monitoring delay-line waveguide MZI 250, and FIG. 6 shows a case where light from the second port of the fourth optical waveguide 205 enters the on-chip monitoring delay-line waveguide MZI 250.
a the on-chip monitoring delay-line waveguide MZI 250 constitutes that: light entering an input port of the on-chip monitoring delay-line waveguide MZI 250 is split by an 1×2 waveguide coupler 251 and split into a first waveguide arm 252 and a second waveguide arm 253, the second waveguide arm 253 is provided with a optical waveguide delay loop, and light propagating in the first waveguide arm 252 and the second waveguide arm 253 merges and is mixed at a first 2×2 waveguide coupler 254 and then split into two output paths; and
the two output paths of the first 2×2 waveguide coupler 254 are coupled into two optical detectors respectively, i.e., 260a and 260b, of the first balanced optoelectric detector 260.

Consequently, as the length of the optical waveguide delay loop (i.e. delay time) on the second waveguide arm 253 is fixed, the change of optical frequency difference between the two arms over time can be inferred from the coherent demodulation with the help of the on-chip monitoring delay Waveguide MZI 250 and the first balanced optoelectric detector 260, and thus the output of the first balanced optoelectric detector 260 can be used as feedback to monitor, calibrate and control the wavelength tuning linearity or chirp of the external-cavity tunable laser A.

### Example 6

On the basis of any one of the Examples 1 to 5 mentioned above, the example 6 discloses additionally the following preferred implementations.

As shown in FIGS. 1a-6, the FMCW lidar further includes a focusing optical lens 700, and the integrated chip 200 is further provided with a third optical waveguide 204, a fourth optical waveguide 205, a fifth optical waveguide 206, a for signal demodulation waveguide MZI 270 and a second balanced optoelectric detector 280;
a first port of the fifth optical waveguide 206 is connected to an facet of the integrated chip 200, and light from a second port of the fifth optical waveguide 206 is coupled into a second input port of the signal demodulation waveguide MZI 270; and the focusing optical lens 700 is placed on an incoming optical path of the first port of the fifth optical waveguide 206, the focusing optical lens 700 and emission port of the external-cavity tunable laser A are on a same side of the integrated chip 200;
a first port of the third optical waveguide 204 and a first port of the fourth optical waveguide 205 are respectively connected to the tunable waveguide filter 230, and the tunable waveguide filter 230 also has the following characteristics that: light coupled to the third optical waveguide 204 by the first optical waveguide 201 through the tunable waveguide filter 230 and light coupled to the fourth optical waveguide 205 by the second optical waveguide 202 through the tunable waveguide filter 230 are both denoted as filtered light; and a light intensity of the filtered light has a spectrum complementary to the transmission spectrum as shown in FIG. 1b;
as both the second port of the third optical waveguide 204 and the second port of the fourth optical waveguide 205 are out-coupling port of the external-cavity tunable laser A, the light exiting from them is the laser light generated by the external-cavity tunable laser A;
laser light from any of a second port of the third optical waveguide 204 and a second port of the fourth optical waveguide 205 is coupled into a first input port of the signal demodulation waveguide MZI 270; among them, FIG. 1a, FIG. 2a to FIG. 4b show a case where light from the second port of the fourth optical waveguide 205 enters the signal demodulation waveguide MZI 270, and FIG. 6 shows a case where light from the second port of the third optical waveguide 204 enters the signal demodulation waveguide MZI 270.
the signal demodulation waveguide MZI 270 constitutes that light from the first input port and the second input port of the signal demodulation waveguide MZI 270 is met and is mixed in a second 2×2 waveguide coupler 271, and then is split into two paths to be coupled into a third waveguide arm 272 and a fourth waveguide arm 273, and then merges and is mixed in a third 2×2 waveguide coupler 274, and then split into two output paths; and
the two output paths by the third 2×2 waveguide coupler 274 are respectively coupled to two optical detectors, i.e., 280a and 280b, of the second balanced optoelectric detector 280.

Thus, when the laser beam L emitted from the external-cavity tunable laser is irradiated to the detection target as a scanning laser beam, a signal light reflected or scattered by the detection target is coupled into the fifth optical waveguide 206 via the focusing optical lens 700 and travels to the second input port of the signal demodulation waveguide MZI 270 to participate in coherent demodulation. The focusing optical lens 700 can be optical devices such as a high numerical aperture NA lens as front-end optics, optical polarization splitting, conversion and combination element, etc., so as to ensure that the signal light gets into the fifth optical waveguide 206 in a single TE polarization state.

The light coupled to the second input port of the signal demodulation waveguide MZI 270 is used as a reference light or a local oscillator, and, together with the signal light gets into the first input port of the signal demodulation waveguide MZI 270, is coherently demodulated through the signal demodulation waveguide MZI 270 and the second balanced optoelectric detector 280. Since a tuning rate of the wavelength or frequency of the laser from the external-cavity tunable laser A can be defined and controllable, the round-trip time of the laser beam L emitted by the external-cavity tunable laser A to the detection target can be obtained by the frequency difference measured through the coherent demodulation of the waveguide MZI 270 and the second balanced optoelectric detector 280, and then the distance from the FMCW lidar to the detection target can be obtained, thus achieving frequency-modulated continuous wave (FMCW) coherent laser ranging.

Furthermore, with a large-angle-range laser detection scanning achieved by the n free-space optical feedback channels and the dispersive optical element 600, the present disclosure enables frequency-modulated continuous-wave FMCW ranging with high-resolution, large-angle solid-state scanning range.

The figures of the present disclosure are schematic and do not represent actual dimensions or values.

The present disclosure is not limited to the above-described implementations, and according to the above-mentioned teachings, other equivalent modifications, substitutions, and alterations, which also fall within the scope of protection of the present disclosure, can be made to the present disclosure in various other forms without departing from the above-described basic technical idea of the present disclosure according to common technical knowledge and customary means in this field.

1. An FMCW lidar based on chip integration, comprising: a light-emission gain chip, an integrated chip, a collimating optical lenses and an optical filtering feedback devices;
the FMCW lidar constituting an external-cavity tunable laser with the following structure that:
the integrated chip is provided with an optical waveguide circuit containing a first optical waveguide and a second optical waveguide; two ports of the first optical waveguide are connected respectively to a broadband optical feedback structure and a tunable waveguide filter; a first port of the second optical waveguide is connected to the tunable waveguide filter, and a second port of the second optical waveguide is configured to emit light out of the integrated chip; and the first optical waveguide or the second optical waveguide passes through a waveguide phase control section; and
light emitted by the light-emission gain chip via its optical waveguide thereof is coupled to the first optical waveguide or the second optical waveguide; and the collimating optical lenses and the optical filtering feedback devices are sequentially placed on an exit optical path of the second optical waveguide.

2. The FMCW lidar based on chip integration according to claim 1, wherein the broadband optical feedback structure is capable of reflecting light along an original path of an incident direction;
the waveguide phase control section is capable of controlling a round trip optical path of a photon in the external-cavity tunable laser to be an integral multiple of a wavelength of a laser beam emitted by the external-cavity tunable laser;
the tunable waveguide filter has the following characteristics that: light coupled to the second optical waveguide by the first optical waveguide and being filtered by the tunable waveguide filter and light coupled to the first optical waveguide by the second optical waveguide and being filtered by the tunable waveguide filter are both denoted as transmission light; a light intensity of the transmission light has a transmission spectrum composed of comb-like transmission peaks, and a separation of center wavelengths of any two adjacent transmission peaks is a fixed Free Spectral Range; and the tunable waveguide filter is capable of tuning simultaneously wavelengths of all the transmission peaks; and
the optical filtering feedback devices are capable of reflecting light of wavelength within a reflection band along the original path of the incident direction, the reflection band having a fixed central wavelength and a reflection wavelength bandwidth smaller than the Free Spectral Range.

3. The FMCW lidar based on chip integration according to claim 2, wherein the external-cavity tunable laser emits the laser beam exiting through the optical filtering feedback devices in such a way that the broadband optical feedback structure is a high-reflectivity broadband optical feedback with a reflectivity higher than a reflectivity preset value; and a reflectivity of the optical filtering feedback devices is lower than the reflectivity preset value.

4. The FMCW lidar based on chip integration according to claim 3, wherein the FMCW lidar is provided with an optical switch and n free-space optical feedback channels, n≥2;
each of the free-space optical feedback channels is provided with one optical filtering feedback device, and with respect to n optical filtering feedback devices corresponding to the n free-space optical feedback channels, exit directions of optical paths of the n optical filtering feedback devices are different from each other, the central wavelengths of the reflection bands of the n optical filtering feedback devices are different and are separated by integer multiples of the Free Spectral Range, and the reflection bands of the n optical filtering feedback devices do not overlap with each other; and
the optical switch is capable of selecting any of the n free-space optical feedback channels for optical coupling to the second optical waveguide.

5. The FMCW lidar based on chip integration according to claim 4, wherein the separation between any two adjacent central wavelengths of the reflection bands in the n optical filtering feedback devices is the Free Spectral Range; and the reflection wavelength bandwidths of the reflection bands in the n optical filtering feedback devices are less than and close to the Free Spectral Range, and the separation between any two adjacent reflection bands is less than a reflectivity preset value.

6. The FMCW lidar based on chip integration according to claim 4, wherein the optical switch is a planar waveguide optical switch on the integrated chip; n branch optical waveguides are provided on the integrated chip corresponding to the n free-space optical feedback channels; and the second port of the second optical waveguide is connected to a main port of the planar waveguide optical switch, n branch ports of the planar waveguide optical switch are respectively connected to one end of n branch optical waveguides, and the other end of the n branch optical waveguides terminates at second facet of the integrated chip; and
each of the free-space optical feedback channels is provided with one collimating optical lens and one optical filtering feedback device; and the collimating optical lens and the optical filtering feedback device in each of the free-space optical feedback channels are placed sequentially along the exit optical path of the corresponding branch optical waveguide.

7. The FMCW lidar based on chip integration according to claim 4, wherein the optical switch is a free-space optical switch, and the free-space optical switch has one main optical port and n branch optical ports respectively corresponding to the n free-space optical feedback channels; and the n free-space optical feedback channels share one single collimating optical lens, and each of the free-space optical feedback channels is provided with one optical filtering feedback device; and
the second port of the second optical waveguide terminates at a second facet of the integrated chip, the collimating optical lens and the main optical port of the free-space optical switch are placed sequentially on the exit optical path of the second optical waveguide, and the n branch optical ports of the free-space optical switch are aligned respectively to incident optical paths of the optical filtering feedback devices of the n free-space optical feedback channels.

8. The FMCW lidar based on chip integration according to claim 7, wherein the free-space optical switch is a micro-electromechanical mirror.

9. The FMCW lidar based on chip integration according to claim 4, wherein exit directions of optical paths of the optical filtering feedback devices of the n free-space optical feedback channels have a fan-out distribution at uniformly spaced angles; and
a dispersive optical element is placed on the exit optical path of the optical filtering feedback device corresponding to the free-space optical feedback channel.

10. The FMCW lidar based on chip integration according to claim 3, wherein a high-reflectivity broadband optical feedback structure as the broadband optical feedback structure comprises that one end of the first optical waveguide terminates at a first facet of the integrated chip, and the first facet of the integrated chip is coated with a broadband high-reflection film with a reflectivity higher than the reflectivity preset value.

11. The FMCW lidar based on chip integration according to claim 3, wherein a high-reflectivity broadband optical feedback structure as the broadband optical feedback structure comprises that the optical waveguide emitting light from the light-emission gain chip is butt-coupled to a facet of the first optical waveguide or a facet of the second optical waveguide through the right facet of the light-emission gain chip; and the left facet of the light-emission gain chip is coated with a broadband high-reflection film with a reflectivity higher than the reflectivity preset value.

12. The FMCW lidar based on chip integration according to claim 3, wherein a high-reflectivity broadband optical feedback structure as the broadband optical feedback structure comprises: a broadband waveguide loop mirror provided on the integrated chip; and the optical waveguide of the light-emission gain chip and the first optical waveguide are coupled inbetween the broadband waveguide loop mirror and the tunable waveguide filter.

13. The FMCW lidar based on chip integration according to claim 1, wherein the external-cavity tunable laser emits the laser beam through the broadband optical feedback structure and the reflectivity of the optical filtering feedback device is higher than the reflectivity preset value; one end of the first optical waveguide terminates at a first facet of the integrated chip, and the broadband optical feedback structure is a broadband reflection film coated on the first facet of the integrated chip with a reflectivity lower than the reflectivity preset value; and a second collimating optical lens is placed on an exit optical path of the first optical waveguide.

14. The FMCW lidar based on chip integration according to claim 1, wherein the FMCW lidar further comprises a dispersive optical element; the dispersive optical element is placed on an exit optical path of an output laser beam of the external-cavity tunable laser.

15. The FMCW lidar based on chip integration according to claim 14, wherein the dispersive optical element is any of, or any combination of multiple of, a diffraction grating, a diffractive optical element, a holographic optical element, and an optical meta-surface device.

16. The FMCW lidar based on chip integration according to claim 2, wherein the integrated chip is further provided with a third optical waveguide, a fourth optical waveguide, an on-chip monitoring delay-line waveguide MZI and a first balanced optoelectric detector;
a first port of the third optical waveguide and a first port of the fourth optical waveguide are respectively connected to the tunable waveguide filter, light coupled to the third optical waveguide by the first optical waveguide via the tunable waveguide filter and light coupled to the fourth optical waveguide by the second optical waveguide via the tunable waveguide filter are both denoted as filtered light; and a light intensity of the filtered light has a spectrum complementary to the transmission spectrum;
as a coupling port of the external-cavity tunable laser, laser light exiting from any one of a second port of the third optical waveguide and a second port of the fourth optical waveguide is transmitted to the first balanced optoelectric detector through the on-chip monitoring delay-line waveguide MZI;
the on-chip monitoring delay-line waveguide MZI comprises that: light input from the input port of the on-chip monitoring delay-line waveguide MZI is split by an 1×2 waveguide coupler and then respectively coupled into a first waveguide arm and a second waveguide arm, the second waveguide arm is provided with a waveguide optical delay-line loop, and light transmitted in the first waveguide arm and the second waveguide arm merges and is mixed in a first 2×2 waveguide coupler and then split into two paths to output; and
two light output from the first 2×2 waveguide coupler are respectively coupled to two optical detectors of the first balanced optoelectric detector.

17. The FMCW lidar based on chip integration according to claim 2, wherein the FMCW lidar further comprises a focusing optical lens, and the integrated chip is further provided with a third optical waveguide, a fourth optical waveguide, a fifth optical waveguide, a signal demodulation waveguide MZI and a second balanced optoelectric detector;
a first port of the fifth optical waveguide is connected to an facet of the integrated chip, and light emitted from a second port of the fifth optical waveguide is input into a second input port of the signal demodulation waveguide MZI; and the focusing optical lens is placed on the incident optical path of the first port of the fifth optical waveguide, and focusing optical lens and the emission of the laser beam from the external-cavity tunable laser are on a same side of the integrated chip;
a first port of the third optical waveguide and a first port of the fourth optical waveguide are respectively connected to the tunable waveguide filter, and the tunable waveguide filter also has the following characteristics that: light coupled to the third optical waveguide by the first optical waveguide via the tunable waveguide filter and light coupled to the fourth optical waveguide by the second optical waveguide via the tunable waveguide filter are both denoted as filtered light; and a light intensity of the filtered light has a spectrum complementary to the transmission spectrum;
as a coupling port of the external-cavity tunable laser, laser light exiting from any one of a second port of the third optical waveguide and a second port of the fourth optical waveguide is input to a first input port of the signal demodulation Waveguide MZI;
the signal demodulation waveguide MZI comprises that light input from the first input port and the second input port of the signal demodulation waveguide MZI merges and is mixed through a second 2×2 waveguide coupler, and then split into two paths couple to a third waveguide arm and a fourth waveguide arm, and then merges and is mixed in a third 2×2 waveguide coupler, and then split into two output paths; and
two light output from the third 2×2 waveguide coupler are respectively coupled into two optical detectors of the second balanced optoelectric detector.

18. The FMCW lidar based on chip integration according to claim 1, wherein light emitted by the light-emission gain chip is coupled into the optical waveguide of the integrated chip via the optical waveguide by waveguide butt-coupling, i.e., the integrated chip is provided with an etched trench, the light-emission gain chip is flip-chip bonded in the trench, and a right facet of the light-emission gain chip is coated with an optical anti-reflection coating; and the facet of the first optical waveguide or the second optical waveguide is coated with an optical anti-reflection coating and extends to the trench so as to be butt-coupled with the optical waveguide of light-emission gain chip that emits light, at its right facet of the light-emission gain chip, and the left facet of the gain chip is coated with a reflection coating with a reflectivity higher than a predetermined value as another feedback mirror of the external-cavity tunable laser.

19. The FMCW lidar based on chip integration according to claim 1, wherein light emitted from the light-emission gain chip is coupled into the optical waveguide of the integrated chip through evanescent wave coupling, i.e., the light-emission gain chip is flip-chip mounted on a surface of the integrated chip, and the optical waveguide of the light-emission gain chip is connected to the first optical waveguide or the second optical waveguide, so that light emitted by the light-emission gain chip is coupled into the first optical waveguide or the second optical waveguide through an optical evanescent wave coupling.

20. The FMCW lidar based on chip integration according to claim 1, wherein the light-emission gain chip is a III-V compound semiconductor active gain chip or a light source chip.

21. The FMCW lidar based on chip integration according to claim 1, wherein the integrated chip is a silicon optical integrated chip or a passive photonic integrated chip.

22. The FMCW lidar based on chip integration according to claim 1, wherein a second facet of the integrated chip is coated with a broadband optical anti-reflection coating.

23. (canceled)

24. (canceled)

25. (canceled)

26. (canceled)

27. (canceled)
